(19) United States
(12) Patent Application Publication
(10) Pub. No.: US 2013/0154478 A1
(43) Pub. Date: Jun. 20, 2013

(54) ORGANIC LIGHT EMITTING DEVICE AND ANTISTATIC METHOD FOR THE SAME

(71) Applicants: Masahito Ohe, Osaka (JP); Katsumi Kondoh, Osaka (JP)

(72) Inventors: Masahito Ohe, Osaka (JP); Katsumi Kondoh, Osaka (JP)

(73) Assignee: SHARP KABUSHIKI KAISHA, Osaka (JP)

(21) Appl. No.: 13/818,290

(22) PCT Filed: Jun. 30, 2011
(86) PCT No.: PCT/JP2011/065046

§ 371 Date: Feb. 21, 2013

(30) Foreign Application Priority Data
Aug. 25, 2010 (JP) 2010-188807

(51) Int. Cl. H01L 51/52; H05B 33/08

(52) U.S. Cl. CPC H01L 51/52; H05B 33/08
USPC 315/85; 257/40; 257/98

(57) ABSTRACT

An organic light emitting device includes first and second substrates, an organic light emitting element between the first and second substrates, a driving unit located between the first and second substrates to drive the organic light emitting element, a fluorescent layer included on a first surface of the first substrate, and a conductive layer with optical transparency included on a second surface of the first substrate, wherein the organic light emitting element includes a light emitting layer, and a pair of electrodes having the light emitting layer interposed therebetween, the fluorescent layer is provided above the electrode on the side from which light emitted from the light emitting layer is extracted among the pair of electrodes, the fluorescent layer performs fluorescence-conversion on a color of the light emitted from the light emitting layer, the fluorescent layer includes a layer that absorbs light having a specific wavelength, the first substrate has optical transparency, light is emitted from the fluorescence conversion layer to the outside through the first substrate, the fluorescent layer is arranged in a surface direction of the first substrate to form a pixel, and the conductive layer overlaps at least an area in which the pixel is formed.

### TECHNICAL FIELD

The present invention relates to an organic light emitting device that counteracts static electricity, and an antistatic method for the same.

Priority is claimed on Japanese Patent Application No. 2010-188807, filed Aug. 25, 2010, the content of which is hereby incorporated herein by reference in its entirety.

### BACKGROUND ART

The present invention relates to an organic electroluminescence element (which may be hereinafter referred to as an organic EL element) and, more specifically, to an organic light emitting device including an organic EL element which has a specific configuration and is capable of realizing a multicolor light emitting element with a wide viewing angle, high color purity, and high efficiency.

In general, an EL element has high visibility due to a self-luminous property and is a completely solid state device. Accordingly, the EL element has excellent impact resistance and is easy to handle. Thus, the EL element has attracted attention for use as a light emitting element in various display devices. The EL element includes an inorganic EL element using an inorganic compound as a light emitting material, and an organic EL element using an organic compound. Among these, the organic EL element has been actively studied for practical realization since an applied voltage can be significantly lowered.

As a configuration of the organic EL element, a device having a configuration basically including an anode/emitting layer/cathode and further including a hole injection and transport layer and an electron injection and transport layer appropriately provided therein, such as a stacked configuration of anode/hole injection and transport layer/light emitting layer/cathode or anode/hole injection and transport layer/light emitting layer/electron injection and transport layer/cathode is known. The hole injection and transport layer has a function of delivering holes injected from the anode to the light emitting layer. Further, the electron injection and transport layer has a function of delivering electrons injected from the cathode to the light emitting layer.

Also, the hole injection and transport layer is interposed between the light emitting layer and the anode, thereby injecting a number of holes into the light emitting layer at a lower electric field. Further, since the hole injection and transport layer does not transport electrons, electrons injected from the cathode or the electron injection and transport layer to the light emitting layer are accumulated at an interface between the hole injection and transport layer and the light emitting layer, thereby improving luminous efficiency, as is known. In order to make such an organic EL element multicolor light emitting elements, for example, in a conventional display, full color is realized by juxtaposing pixels emitting red, green and blue light as one unit to produce a variety of colors represented by white color. That is, a white color filtering method of converting emitted white light into red, green and blue light using a color filter for multi-color light emission is known (See Non-Patent Document 1).

In order to realize the structure described above, a method of forming red, green, and blue pixels by separately coating an organic light emitting layer through a mask deposition method using a shadow mask is generally used in the case of an organic EL element. However, in this method, it is necessary to improve processing accuracy of the mask, improve mask alignment accuracy and increase the size of the mask. In particular, in the field of a large display represented by a TV, the substrate size has increased from a so-called G6 generation to a G8 generation and to a G10 generation. In the case of a conventional method, since a mask having a size equal to or greater than the substrate size is necessary, it is necessary to fabricate and process a mask corresponding to a large substrate. However, since the mask is required to be a very thin metal (a typical thickness: 50 nm to 100 nm), it is difficult to obtain a large size for the mask.

Further, it is difficult to fabricate and process a mask corresponding to a large substrate. A decrease in mask processing accuracy and mask alignment accuracy may cause color mixing in a light emitting layer. Further, in order to prevent the decrease in the mask processing accuracy and the mask alignment accuracy, it is necessary to increase a width of an insulating layer typically provided between pixels. When an area of the pixel has been determined, an area of a non-emitting portion decreases, i.e., an aperture ratio of the pixel decreases, leading to luminance degradation, power consumption increase, and lifespan reduction. Further, in a conventional manufacturing method, a deposition source is arranged below a substrate and deposits an organic material in a direction from bottom to top to form an organic light emitting layer. Accordingly, the mask is deflected at a central portion with an increase in a size of the substrate (an increase in a size of the mask). Here, the deflection of the mask causes the above-described color mixing. Further, in extreme cases, a portion in which an organic light emitting layer has not been formed is generated and leakage (electrical short-circuit) of upper and lower electrodes occurs.

Further, in the conventional method, when the mask is used a certain number of times, the mask is unusable due to deterioration thereof. Accordingly, a large mask leads to an increase in display cost.

Accordingly, organic light emitting devices that emit full color light by combining an organic EL having a light emitting layer that emits blue to blue-green light, a green pixel including a fluorescent layer that absorbs the blue to blue-green light from the organic EL and emits green light, a red pixel including a fluorescent layer that emits red light, and a blue pixel including a blue color filter intended to improve color purity has been proposed (see Patent Documents 1, 2 and 3). These devices are superior to those utilizing a separate coating method since patterning of the organic light emitting layer is not required, manufacture is easier, and cost is lowered.

### Patent Documents

Patent Document 1: Japanese Patent No. 2795932
Patent Document 2: Japanese Patent Laid-Open Publication No. H3-152897
Patent Document 3: Japanese Patent Laid-Open Publication No. H5-258860
Patent Document 4: Japanese Patent Laid-Open Publication No. H9-105918

### Non-Patent Document

Non-Patent Document 1: White color filter method, “Semicond. Sci. Technol.” Vol. 6, pages 305 to 323 (1991)

### SUMMARY OF INVENTION

### Problem to be Solved by the Invention

However, in this type of organic light emitting device, display abnormality occurs when a high potential of static electricity or the like is applied from an outside side of a surface of a display panel.

Regarding this, the present inventors have found the following causes of such display abnormality from their study.

That is, in an organic light emitting device, an anode and a cathode are arranged in parallel or substantially parallel, with an organic light emitting layer interposed therebetween. The organic light emitting device has a configuration in which no conductive layer having a shielding function against external static electricity or the like is included between the anode and the cathode. When such a conductive layer is arranged, an electric field from the anode and the cathode is terminated at the conductive layer and appropriate display by current cannot be realized.

Also, since the organic light emitting device of the prior art does not have the shielding function as described above, an electric field between the anode and the cathode which is generated substantially perpendicular to a transparent substrate is affected by external static electricity or the like. This external static electricity or the like is charged in the display panel itself. This charging interferes with an electric field generated by a current injection electrode.

Further, the charged static electricity is likely to destroy active elements, such as TFTs (thin film transistors) used as units for display driving provided on the substrate of the organic light emitting device.

On the other hand, for example, in the case of a vertical electric field type liquid crystal display device, each of a pixel electrode and a common electrode arranged to oppose each other via liquid crystal necessarily has a shielding function against external static electricity or the like. Thus, the phenomenon as described above is not observed.

Further, in a horizontal electric field type liquid crystal display device, technology for enhancing the effects of static electricity or the like by providing a conductive layer on an outer side of a transparent substrate to which a polarizing plate is bonded, i.e., on the side of the transparent substrate opposite a liquid crystal layer, with respect to one of substrates having liquid crystal interposed therebetween is known. (See Patent Document 4)

One embodiment of the present invention relates to an organic light emitting device capable of preventing the occurrence of a display abnormality even when a high potential of static electricity or the like is applied from the outside of a surface of a substrate on the display side of the organic light emitting device.

One aspect of the present invention is made based on the background as described above, and provides an organic light emitting device described below.

### Means for Solving the Problem

A typical aspect of the present invention among aspects of the present invention will be briefly described as follows.

An organic light emitting device according to an aspect of the present invention includes first and second substrates; an organic light emitting element between the first and second substrates; a driving unit located between the first and second substrates to drive the organic light emitting element; a fluorescent layer provided on a first surface of the first substrate; and a conductive layer with optical transparency provided on a second surface of the first substrate, wherein the organic light emitting element includes a light emitting layer, and a pair of electrodes having the light emitting layer interposed therebetween, the fluorescent layer is provided above the electrode on the side from which light emitted from the light emitting layer is extracted among the pair of electrodes, the fluorescent layer performs fluorescence-conversion on a color of the light emitted from the light emitting layer, the fluorescent layer includes a layer that absorbs light having a specific wavelength, the first substrate has optical transparency, light is emitted from the fluorescence conversion layer to the outside through the first substrate, the fluorescent layer is arranged in a surface direction of the first substrate to form a pixel, and the conductive layer overlaps at least an area in which the pixel is formed.

An organic light emitting device according to an aspect of the present invention includes first and second substrates; an organic light emitting element between the first and second substrates; a fluorescent layer between the first substrate and the organic light emitting element; and a conductive layer with optical transparency between the first substrate and the fluorescent layer, wherein the organic light emitting element includes a light emitting layer, and a pair of electrodes having the light emitting layer interposed therebetween, the fluorescent layer is provided above the electrode on the side from which light emitted from the light emitting layer is extracted among the pair of electrodes, the fluorescent layer performs fluorescence-conversion on a color of the light emitted from the light emitting layer, and the fluorescent layer includes a layer that absorbs light having a specific wavelength.

An organic light emitting device according to an aspect of the present invention includes an organic light emitting element; a driving unit that drives the organic light emitting element; and a fluorescent layer on the organic light emitting element, wherein the organic light emitting element includes a light emitting layer, and a pair of electrodes having the light emitting layer interposed therebetween, the fluorescent layer is provided above the electrode on the side from which light emitted from the light emitting layer is extracted among the pair of electrodes, the fluorescent layer performs fluorescence-conversion on a color of the light emitted from the light emitting layer, the fluorescent layer includes a layer that absorbs light having a specific wavelength, and conductive particles are mixed within the fluorescent layer.

An organic light emitting device according to an aspect of the present invention includes an organic light emitting element; a fluorescent layer on the organic light emitting element; and a conductive layer arranged within the fluorescent layer or in contact with the fluorescent layer, wherein the organic light emitting element includes a light emitting layer, and a pair of electrodes having the light emitting layer interposed therebetween, the fluorescent layer is provided above the electrode on the side from which light emitted from the light emitting layer is extracted, the fluorescent layer performs fluorescence-conversion on a color of the light emitted from the light emitting layer, and the fluorescent layer includes a layer that absorbs light having a specific wavelength

Further, in an aspect of the present invention, it is also effective for the conductive particles to be mixed inside the fluorescent layer, as well as on the substrate surface. An antistatic effect occurs since electrical conductivity is present inside the fluorescent layer. Also, a structure in which the conductive film is applied to a portion in contact with the fluorescent layer may be adopted. Accordingly, in these cases, a conductive thin film of a metal or the like may be used in an interface between the fluorescent layer and the substrate, an interface between the fluorescent layer and a film formed on the organic light emitting layer side of the fluorescent layer film, or a film that partitions the fluorescent layers for respective colors.

With regard to electrical conductivity of the conductive layer, a sheet resistance of the conductive layer may be 2×10³Ω·□ or less. It is advantageous to obtain a sufficient antistatic effect.

The conductive layer may have unevenness or may have a periodic structure. The conductive layer or the conductive particles may be formed of a metal.

The conductive layer may be connected to a ground terminal provided on the substrate.

The conductive layer or the conductive particles may be formed of particles containing any one of ITO, SnO₂ and In₂O₃ or a mixture of the particles.

The pair of electrodes having the light emitting layer interposed therebetween may be reflective electrodes, and an optical film thickness between reflective interfaces defined by the pair of reflective electrodes may be set to enhance the intensity of light having a specific wavelength among light emitted from the light emitting layer.

An antistatic method for an organic light emitting device according to an aspect of the present invention is an antistatic method for an organic light emitting device including first and second substrates, an organic light emitting element between the first and second substrates, and a fluorescent layer included on a first surface of the first substrate, the organic light emitting element including a light emitting layer and a pair of electrodes having the light emitting layer interposed therebetween, the fluorescent layer being provided above the electrode on the side from which light emitted from the light emitting layer is extracted among the pair of electrodes, the fluorescent layer performing fluorescence-conversion on a color of the light emitted from the light emitting layer, and the fluorescent layer including a layer that absorbs light having a specific wavelength, wherein a conductor is arranged in the first substrate to prevent charging of the organic light emitting element.

An antistatic method for an organic light emitting device according to an aspect of the present invention is an antistatic method for an organic light emitting device including first and second substrates, an organic light emitting element between the first and second substrates, and a fluorescent layer included on a first surface of the first substrate, the organic light emitting element including a light emitting layer and a pair of electrodes having the light emitting layer interposed therebetween, the fluorescent layer being provided above the electrode on the side from which light emitted from the light emitting layer is extracted among the pair of electrodes, the fluorescent layer performing fluorescence-conversion on a color of the light emitted from the light emitting layer, and the fluorescent layer including a layer that absorbs light having a specific wavelength, wherein a conductor is arranged inside the fluorescent layer or around the fluorescent layer to prevent charging of the organic light emitting element.

In an antistatic method for an organic light emitting device according to an aspect of the present invention, the conductor provided in the above substrate or the conductor provided inside the fluorescent layer or around the fluorescent layer may be grounded through connection to a power supply for the pair of electrodes having the light emitting layer interposed therebetween.

### Effect of Invention

According to one aspect of the present invention, a conductive layer with a light transmission property is formed in at least a portion overlapping the pixel formation area of the substrate at a distance from the light emitting layer among the substrates of the organic light emitting device, i.e., the substrate on the observation side, that is, in a display area, such that the conductive layer has a shielding function against static electricity or the like from the outside of the device. Further, even in a structure in which the conductive layer is provided between the fluorescent layer and the substrate, a structure in which the conductive particles are mixed in the fluorescent layer, or a structure in which the conductive layer is provided within the fluorescent layer or to be in contact with the fluorescent layer, the conductive layer has the shielding function against static electricity or the like from the outside of the device.

### BRIEF DESCRIPTION OF DRAWINGS

FIG. 1A is a schematic cross-sectional view illustrating an example of an organic light emitting device according to a first embodiment of the present invention.

FIG. 1B is a plan view illustrating a pixel arrangement of the organic light emitting device according to the first embodiment of the present invention.

FIG. 2 is a schematic cross-sectional view illustrating an organic EL element constituting a primary portion of an organic light emitting device according to a second embodiment of the present invention.

FIG. 3 is a schematic cross-sectional view illustrating an organic EL element constituting a primary portion of an organic light emitting device according to a third embodiment of the present invention.

FIG. 4 is a schematic cross-sectional view illustrating an organic EL element constituting a primary portion of an organic light emitting device according to a fourth embodiment of the present invention.

FIG. 5 is a schematic cross-sectional view illustrating an organic EL element constituting a primary portion of an organic light emitting device according to a fifth embodiment of the present invention.

FIG. 6 is a schematic cross-sectional view illustrating an organic EL element constituting a primary portion of an organic light emitting device according to a sixth embodiment of the present invention.

FIG. 7 is a schematic cross-sectional view illustrating an organic laser element constituting a primary portion of an organic light emitting device according to a seventh embodiment of the present invention.

FIG. 8 is a schematic configuration diagram illustrating an example of a laser pointer using the organic laser element.

FIG. 9 is a schematic cross-sectional view illustrating an example of an organic light emitting device according to an eighth embodiment of the present invention.

FIG. 10 is a circuit diagram illustrating an example of a peripheral circuit included in the organic light emitting device.

### DESCRIPTION OF EMBODIMENTS

### First Embodiment

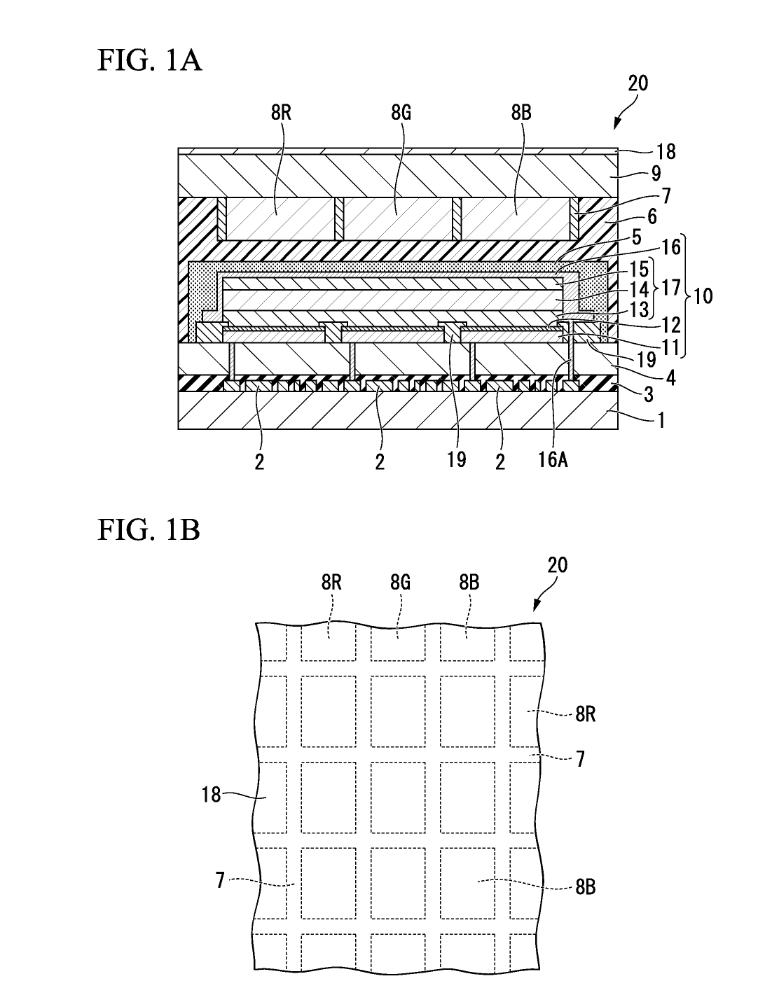

FIGS. 1A and 1B are views illustrating an example of an organic light emitting device according to a first embodiment of the present invention. In each figure subsequent to FIG. 1A, each member is shown on a different scale so that the member has a size that can be recognized in the figures.

A top emission type fluorescent display device 20 as an example of an organic light emitting device illustrated in FIG. 1A schematically includes a substrate 1, an organic EL element (a light source) 10, a sealing substrate 9, and a red fluorescent layer 8R, a green fluorescent layer 8G, and a blue fluorescent layer 8B as fluorescence conversion films (hereinafter referred to as fluorescent layers). The substrate 1 includes a TFT (Thin Film Transistor) circuit 2. The organic EL element (the light source) 10 is provided over the substrate 1. The red fluorescent layer 8R, the green fluorescent layer 8G, and the blue fluorescent layer 8B are divided by a black matrix 7 and arranged in parallel on one surface of the sealing substrate 9 (a surface on the organic EL element side). The substrate 1 and the sealing substrate 9 are arranged so that the organic EL element 10 and the respective fluorescent layers 8R, 8G and 8B face each other with a sealing material 6 interposed therebetween.

The organic EL element 10 of the present embodiment includes a pair of electrodes 12 and 16, and a light emitting layer 14 interposed between the pair of electrodes. The fluorescence conversion layer (hereinafter referred to as a fluorescent layer) is provided above the electrode 16 on the side from which light emitted from the light emitting layer 14 is extracted. A conductive film 18 is formed on a side of the sealing substrate 9 at a distance from the light emitting layer 14, i.e., on an outer side that is a light extraction side of the sealing substrate 9. Details of the structure illustrated in FIG. 1A will be described below.

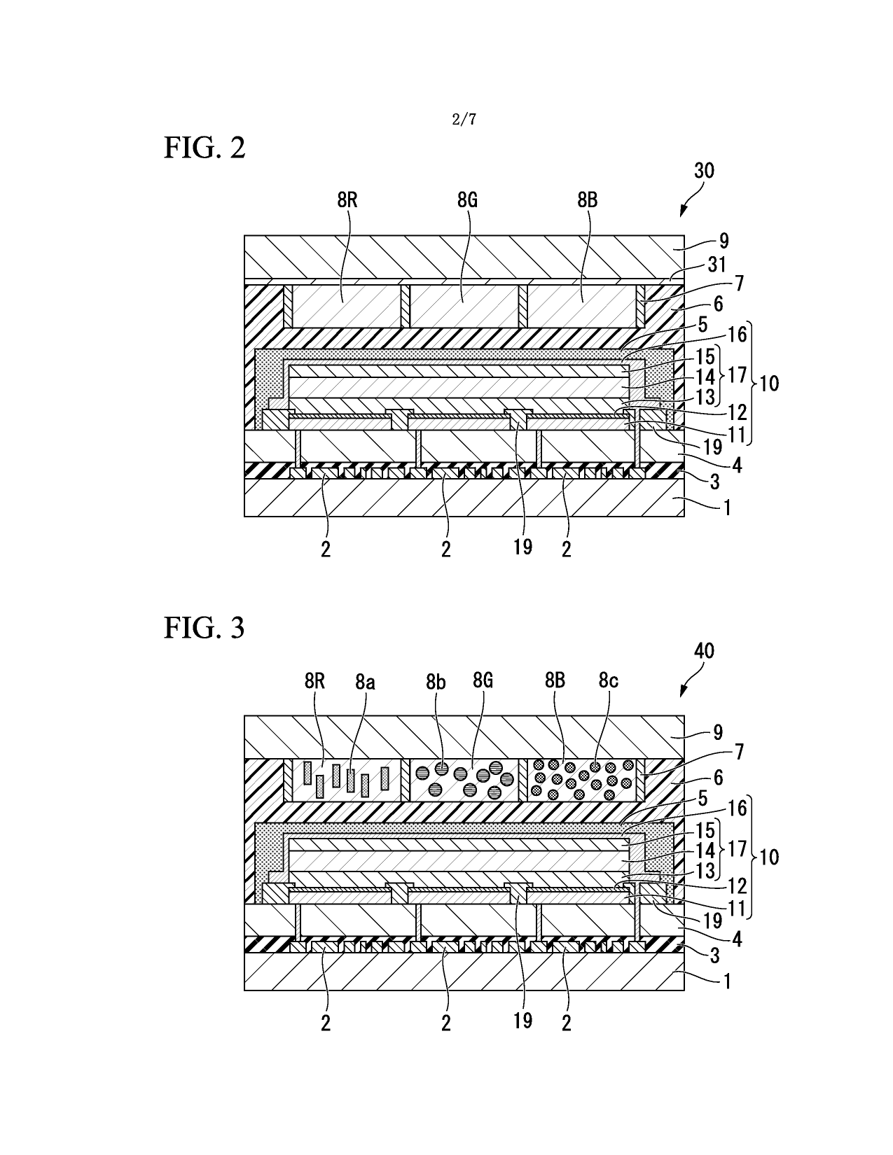

In the fluorescent display device 20 of this embodiment, the light emitted from the organic EL element 10, which is the light source, is incident on the respective fluorescent layers 8R, 8G and 8B. This incident light is converted by the respective fluorescent layers 8R, 8G and 8B and emitted toward the sealing substrate 9 (toward an observer) as three color of light of red, green and blue light. Accordingly, the fluorescent display device 20 can be applied to an organic EL display, an organic EL display element or the like. Further, when the device is configured as an organic EL display or an organic EL display element capable of color display, the fluorescent layers 8R, 8G and 8B are arranged, for example, in a matrix vertically and horizontally as illustrated in FIG. 1B. A set of the fluorescent layers 8R, 8G and 8B constitutes one pixel. A required number of pixels are collected vertically and horizontally so that color image display is possible. Further, an arrangement configuration of the fluorescent layers 8R, 8G and 8B in FIG. 2 is a vertical stripe arrangement. The vertical stripe arrangement illustrated in FIG. 2 as well as other arrangement configurations such as a mosaic arrangement or a delta arrangement may be used as the RGB arrangement.

Next, if the light emitted from the organic EL element 10, which is the light source, is ultraviolet blue light, it is desirable for a fluorescent layer that receives the ultraviolet blue light and emits red light to be adopted in the fluorescent layer 8R, a fluorescent layer that receives the ultraviolet blue light and emits green light to be adopted in the fluorescent layer 8G, and a fluorescent layer that receives the ultraviolet blue light and emits blue light to be adopted in the fluorescent layer 8B. Further, if the light emitted from the organic EL element 10, which is the light source, is ultraviolet blue light or blue light, a fluorescent layer that receives the ultraviolet blue light and emits red light is adopted in the fluorescent layer 8R, a fluorescent layer that receives the ultraviolet blue light and emits green light is adopted in the fluorescent layer 8G, and fluorescent emission is not performed and the light emitted from the organic EL element 10 may be directly transmitted in the fluorescent layer 8B. A structure and color conversion mechanism of each fluorescent layer will be described in detail later.

Hereinafter, an internal structure of the fluorescent display device 20 will be described in detail.

### 1. Substrate

A TFT circuit (a driving unit) 2 and various wirings (not shown) are formed over the substrate 1. In order to cover an upper surface of the substrate 1 and the TFT circuit 2, an interlayer insulating film 3 and a planarizing film 4 are formed to be sequentially stacked.

An example of the substrate 1 may include an inorganic material substrate formed of glass, quartz or the like, a plastic substrate formed of polyethylene terephthalate, polycarbazole, a polyimide or the like, an insulating substrate such as a ceramic substrate formed of alumina or the like, a metal substrate formed of aluminum (Al), iron (Fe) or the like, a substrate obtained by coating a surface of the above substrate with an insulating material including an organic insulating material such as silicon oxide (SiO₂), or a substrate obtained by performing an insulating treatment on a surface of a metal substrate formed of Al or the like using an anodic oxidation method or the like, but the present embodiment is not limited thereto. Among these, it is preferable to use the plastic substrate or the metal substrate since a curved portion or a bent portion can be formed without stress.

Further, it is more preferable to use a substrate obtained by coating a plastic substrate with an inorganic material or a substrate obtained by coating a metal substrate with an inorganic insulating material. Accordingly, deterioration of the organic EL element 10 caused by permeation of moisture likely to occur when the plastic substrate is used as a substrate for the organic EL element 10 can be prevented. The organic EL element 10 is particularly deteriorated even due to a low amount of moisture. Further, leakage (short-circuit) due to protrusions of the metal substrate likely to occur when a metal substrate is used as the substrate of the organic EL element 10 (it has been found that leakage of current (short-circuit) occurs highly in a pixel portion due to the protrusions since a film thickness of each film constituting the organic EL element 10 is as small as 100 nm to 200 nm) can be prevented.

Since the TFT circuit 2 is formed on the substrate 1, it is preferable to use a substrate that is not melted and distorted at temperatures of 500° C. or less. When a metal substrate is used as the substrate 1, it is preferable to use a metal substrate formed of an iron-nickel based alloy having a linear expansion coefficient of 1×10⁻⁵/° C. or less. Since a general metal substrate has a different thermal expansion coefficient from glass, it is difficult to form the TFT circuit 2 on the metal substrate using a conventional production apparatus. However, the TFT circuit 2 can be formed on the metal substrate at a low cost using the conventional production apparatus by matching the linear expansion coefficient with the glass using a metal substrate formed of the iron-nickel based alloy having a linear expansion coefficient of 1×10⁻⁵/° C. or less. Further, when the plastic substrate is used as the substrate 1, a heat resistant temperature is very low. Accordingly, the TFT circuit 2 can be transfer-formed on the plastic substrate by forming the TFT circuit 2 on the glass substrate and then transferring a TFT substrate 2 to the plastic substrate.

Further, when light emitted from the organic EL layer 17 is extracted from the side opposite the substrate 1, there is no constraint on the substrate 1. However, when the light emitted from the organic EL layer 17 is extracted from the substrate 1 side, it is necessary to use a transparent or semi-transparent substrate 1 in order to extract the light emitted from the organic EL layer 17 to the outside as the substrate 1 to be used.

### 2. TFT

The TFT circuit 2 is formed on the substrate 1 in advance before the organic EL element 10 is formed and functions as a switching and driving circuit. As the TFT circuit 2, a conventional known TFT circuit 2 may be used. Further, in the present embodiment, a diode having a metal-insulator-metal (MIM) structure may be used in place of the TFT for switching and driving.

The TFT circuit 2 used in the present embodiment may be formed using a known material, structure and forming method. An example of a material of an active layer of the TFT circuit 2 may include an inorganic semiconductor material such as amorphous silicon (amorphous Si), polycrystalline silicon (poly-Si), microcrystalline silicon, or cadmium selenide, an oxide semiconductor material such as a zinc oxide or indium oxide-gallium oxide-zinc oxide, or an organic semiconductor material such as a polythiophene derivative, a thiophene oligomer, a poly(p-phenylenevinylene) derivative, naphthacene, or pentacene. Further, examples of a structure of the TFT circuit 2 may include a stagger type structure, a reverse stagger type structure, and a top-gate structure, and a coplanar type structure.

Methods of forming the active layer constituting the TFT circuit 2 may include (1) a method of ion-doping impurities into an amorphous silicon film formed by a Plasma Enhanced Chemical Vapor Deposition (PECVD) method, (2) a method of forming an amorphous silicon by a Low Pressure Chemical Vapor Deposition (LPCVD) method using silane (SiH₄) gas, crystallizing amorphous silicon using a solid-phase growth method to obtain polysilicon, and then performing ion doping using a ion implantation method, (3) a method of forming amorphous silicon by an LPCVD method using Si₂H₆ gas or a PECVD method using SiH₄ gas, performing annealing using a laser such as an excimer laser, crystallizing the amorphous silicon to obtain polysilicon, and then performing ion doping (a low temperature process), (4) a method of forming a polysilicon layer using an LPCVD method or a PECVD method, forming a gate insulating film through thermal oxidation at 1000° C. or more, forming a gate electrode of n⁺ polysilicon on the gate insulating film, and then performing ion doping (a high-temperature process), (5) a method of forming an organic semiconductor material using an ink jet method or the like, and (6) a method of obtaining a single crystal film of an organic semiconductor material.

A gate insulating film of the TFT circuit 2 used in the present embodiment may be formed of a known material. An example of the material may include SiO₂ formed by a PECVD method, an LPCVD method or the like or SiO₂ obtained by thermal oxidation of a polysilicon film. Further, a signal electrode line, a scanning electrode line, a common electrode line, a first driving electrode and a second driving electrode of the TFT circuit 2 used in the embodiment may be formed of a known material, and an example of the material may include tantalum (Ta), aluminum (Al), or copper (Cu). The TFT circuit 2 of the organic EL element 10 according to the present embodiment may be formed to have the configuration as described above, but the present embodiment is not limited to such a material, structure, or forming method.

### 3. Interlayer Insulating Film

The interlayer insulating film 3 used in the present embodiment may be formed of a known material, and an example of the material may include an inorganic material such as a silicon oxide (SiO₂), a silicon nitride (SiN or Si₂N₄), or a tantalum oxide (TaO or Ta₂O₅), or an organic material such as an acrylic resin or a resist material. Further, a method of forming the interlayer insulating film 3 may include a dry process such as a chemical vapor deposition (CVD) method or a vacuum deposition method, or a wet process such as a spin coating method. Also, the interlayer insulating film 3 may be patterned by a photolithography method or the like, as necessary.

In the fluorescent display device 20 of the present embodiment, the light emitted from the organic EL element 10 is extracted from the side opposite the substrate 1 (each fluorescent layer 8R, 8G or 8B side), as will be described below. Accordingly, it is preferable to use the interlayer insulating film 3 with a light-shielding property (a light-shielding insulating film) for the purpose of preventing TFT characteristics from being changed due to external light being incident on the TFT circuit 2 formed on the substrate 1. Further, in this embodiment, the interlayer insulating film 3 described above and a light-shielding insulating film may be used in combination. The light-shielding insulating film may include a film in which a pigment or dye such as phthalocyanine or quinacrodone is dispersed in a polymer resin such as polyimide, or an inorganic insulating material such as a color resist, a black matrix material, or NiₓZn_{y}Fe₂O₄. However, the present embodiment is not limited to such material and forming method.

### 4. Planarizing Film

The planarizing film 4 is provided in order to prevent the following phenomena from occurring in the organic EL element 10 due to the unevenness of the surface of the TFT circuit 2. As the phenomena that may occur in the organic EL element 10, there are, for example, a defect of a pixel electrode, a defect of the organic EL layer, disconnection of an opposing electrode, a short-circuit between the pixel electrode and the opposing electrode, and a decrease in a withstand voltage. Further, the planarizing film 4 may be omitted.

The planarizing film 4 may be formed of a known material, and examples of the material may include an inorganic material such as a silicon oxide, a silicon nitride, or a tantalum oxide, and an organic material such as a polyimide, an acrylic resin, or a resist material. A method of forming the planarizing film 4 may include a dry process such as a CVD method or a vacuum deposition method, or a wet process such as a spin coating method, but the present embodiment is not limited to such a material and forming method. Further, the planarizing film 4 may have either a single-layer structure or a multilayer structure.

### 5. Organic EL Element

The organic EL element 10 that is a light source (a light emitting source) is formed on the planarizing film 4. The organic EL element 10 includes a first electrode 12, a second electrode 16, and an organic EL layer (an organic layer) 17. The first electrode 12 is an anode. The second electrode 16 is a cathode arranged opposite the first electrode 12. The organic EL layer 17 (the organic layer) is formed as at least one layer including a light emitting layer 14 interposed between the first electrode 12 and the second electrode 16. The first electrode 12 and the second electrode 16 function, as a pair, as an anode or a cathode for the organic EL element 20. In other words, when the first electrode 12 is the anode, the second electrode 16 is the cathode. Further, when the first electrode 12 is the cathode, the second electrode 16 is the anode. In FIG. 1A and the following description, a case in which the first electrode 12 is the anode and the second electrode 16 is the cathode will be described by way of example. Further, when the first electrode 12 is the cathode and the second electrode 16 is the anode, a hole injection layer and a hole transport layer may be disposed at a side of the second electrode 16, and an electron injection layer and an electron transport layer may be disposed at a side of the first electrode 12, in the stacked structure of the organic EL layer 17 that will be described below.

### 5-1. Organic EL Layer

The organic EL layer 17 may be a single-layer structure of the light emitting layer 14 or may be a multilayer structure like a stacked structure of the hole transport layer 13, the light emitting layer 14 and the electron transport layer 15, as illustrated in FIG. 1A. Specifically, the organic EL layer may include layered structures described in (1) to (9) below, but the present embodiment is not limited thereto. Further, in the configuration that will be described below, a hole injection layer and the hole transport layer 13 are arranged on the side of the first electrode 12, which is the anode. Further, an electron injection layer and the electron transport layer 15 are arranged on the side of the second electrode 16, which is the cathode.

(1) Light emitting layer 14

(2) hole transport layer 13/light emitting layer 14

(3) light emitting layer 14/electron transport layer 15

(4) hole transport layer 13/light emitting layer 14/electron transport layer 15

(5) hole injection layer/hole transport layer 13/light emitting layer 14/electron transport layer 15

(6) hole injection layer/hole transport layer 13/light emitting layer 14/electron transport layer 15/electron injection layer

(7) hole injection layer/hole transport layer 13/light emitting layer 14/hole blocking layer/electron transport layer 15

(8) hole injection layer/hole transport layer 13/light emitting layer 14/hole blocking layer/electron transport layer 15/electron injection layer

(9) hole injection layer/hole transport layer 13/electron blocking layer/light emitting layer 14/hole blocking layer/electron transport layer 15/electron injection layer.

Here, each of the light emitting layer 14, the hole injection layer, the hole transport layer 13, the hole blocking layer, the electron blocking layer, the electron transport layer 15 and the electron injection layer may be a single-layer structure or a multilayer structure.

The light emitting layer 14 may be formed of only an organic light emitting material, may be formed of a combination of a light emitting dopant and a host material, or may arbitrarily include a hole transport material, an electron transport material, an additive agent (e.g., donors or acceptors) or the like. Further, the light emitting layer 14 may have a configuration in which such a material may be dispersed in a polymer material (a binding resin) or an inorganic material. From the viewpoint of luminous efficiency and lifespan, a layer in which the light emitting dopant is dispersed in the host material is preferred. As the light emitting layer 14, a layer in which the holes injected from the first electrode 12 and electrons injected from the second electrode 16 are recombined and, for example, light in an ultraviolet blue area (wavelength: 350 nm to 500 nm) applied in the present embodiment is released (emitted) is used.

As the organic light emitting material used in the light emitting layer 14, a conventionally known light emitting material for organic EL may be used or a material that emits light in an ultraviolet blue area may be used. As the organic light emitting material, either a low-molecular organic light emitting material or a high-molecular organic light emitting material may be used. Further, as the organic light emitting material, either a fluorescent material or a phosphorescent material may be used. From the viewpoint of low power consumption, it is preferable to use a phosphorescent material with high luminous efficiency.

An example of the low-molecular organic light emitting material may include a fluorescent organic material, such as an aromatic dimethylidene compound such as 4,4′-bis(2,2′-diphenyl-vinyl)-biphenyl (DPVBi), an oxadiazole compound such as 5-methyl-2-[2-[4-(5-methyl-2-benzoxazolyl)phenyl]vinyl]benzoxazole, a triazole derivative such as 3-(4-biphenylyl)-4-phenyl-5-t-butylphenyl-1,2,4-triazole (TAZ), a styrylbenzene compound such as 1,4-bis(2-methylstyryl)benzene, or a fluorenone derivative.

Examples of the high-molecular light emitting material may include a polyphenylene vinylene derivative such as poly(2-decyloxy-1,4-phenylene) (DO-PPP) or a polyspiro derivative such as poly(9,9-dioctylfluorene) (PDAF).

When the light emitting layer 14 is formed as the combination of the light emitting dopant and the host material, a conventional known dopant material for organic EL may be used as the light emitting dopant. Examples of such a dopant material may include a fluorescent light emitting material such as a styryl derivative, and a phosphorescent organometallic complex such as bis[(4,6-difluorophenyl)-pyridinato-N,C2′]picolinate iridium (III) (FIrpic), bis(4′,6′-difluorophenyl polydinato)tetrakis(1-pyrazoyl)borate iridium (III) (FIr6).

Further, as a host material when the light emitting dopant is used, a conventionally known host material for organic EL may be used. Such a host material may include the low-molecular organic light emitting material described above, the polymer organic light emitting material described above, a carbazole derivative such as 4,4′-bis(carbazole) biphenyl, 9,9-di(4-dicarbazole-benzyl)fluorene (CPF), 3,6-bis(triphenylsilyl)carbazole (mCP), poly(N-octyl-2,7-carbazole-O-9,9-dioctyl-2,7-fluorene) (PCF), an aniline derivative such as 4-(diphenyl phosphate foil)-N,N-diphenyl aniline (HM-Al), or a fluorene derivative such as 1,3-bis(9-phenyl-9H-fluoren-9-yl)benzene (mDPFB), 1,4-bis(9-phenyl-9H-fluoren-9-yl)benzene (pDPFB).

The charge injection and transport layer is classified into the charge injection layer (the hole injection layer and the electron injection layer) and the charge transport layer (the hole transport layer and the electron transport layer) for the purpose of more efficiently performing injection from the electrode and transport (injection) to the light emitting layer of charges (holes and electrons). The hole injection layer and the hole transport layer 13 are provided between the first electrode 12 and the light emitting layer 14 for the purpose of more efficiently performing the injection from the first electrode 12 that is the anode and transport (injection) to the light emitting layer 14 of the holes. The electron injection layer and the electron transport layer 15 are provided between the second electrode 16 and the light emitting layer 14 for the purpose of more efficiently performing the injection from the second electrode 16 that is the cathode and transport (injection) to the light emitting layer 14 of the electrons.

The hole injection layer, the hole transport layer 13, the electron injection layer, and the electron transport layer 15 may be formed using a conventionally known material, may be formed of only a material illustrated below, may contain an additive agent (e.g., donors or acceptors), or may be formed by dispersing such material in a polymer material (a binding resin) or an inorganic material.

Examples of the material constituting the hole transport layer 13 may include an oxide such as vanadium oxide (V₂O₅) or molybdenum oxide (MoO₂), an inorganic p-type semiconductor material, a low-molecular-weight material such as a porphyrin compound, an aromatic tertiary amine compound such as N,N′-bis(3-methylphenyl)-N,N′-bis(phenyl)-benzidine (TPD) or N,N′-di(naphthalen-1-yl)-N,N′-diphenyl-benzidine (NPD), a hydrazone compound, a quinacridone compound, or a styrylamine compound, and a polymer material such as polyaniline (PANI), polyaniline-camphorsulfonic acid (polyaniline-camphorsulfonic acid; PANI-CSA), 3,4-polyethylene dioxythiophene/polystyrene sulfonate (PEDOT/PSS), a poly(triphenylamine) derivative (Poly-TPD), polyvinyl carbazole (PVCz), poly(p-phenylene vinylene) (PPV), or poly(p-naphthalene vinylene) (PNV).

Further, in terms of more efficient transport and injection of holes from the first electrode 12 that is the anode, it is preferable to use, as the material used as the hole injection layer, a material whose energy level of the highest occupied molecular orbital (HOMO) is lower than that of the material used for the hole transport layer 13. It is preferable to use, as the hole transport layer 13, a material whose hole mobility is higher than that of the material used for the hole injection layer.

Examples of the material for forming the hole injection layer may include a phthalocyanine derivative such as copper phthalocyanine, an amine compound such as 4,4′,4″-tris(3-methylphenylamino)triphenylamine, 4,4′,4″-tris(1-naphthylphenylamino)triphenylamine, 4,4′,4″-tris(2-naphthylphenylamino)triphenylamine, 4,4′,4″-tris[biphenyl-2-yl(phenyl)amino]triphenylamine, 4,4′,4″-tris[biphenyl-3-yl(phenyl)amino]triphenylamine, 4,4′,4″-tris[biphenyl-4-yl(3-methylphenyl)amino]triphenylamine, or 4,4′,4″-tris[9,9-dimethyl-2-fluorenyl(phenyl)amino]triphenylamine, and an oxide such as vanadium oxide (V₂O₅) or molybdenum oxide (MoO₂). However, the material is not limited thereto.

Further, it is preferable to dope the hole injection layer and the hole transport layer 13 with acceptors in order to further improve injection and transport of the holes. For the acceptors, a conventionally known material may be used as an acceptor material for organic EL.

Further, it is preferable to dope the hole injection and transport material with acceptors in order to further improve injection and transport of holes. As the acceptors, a known acceptor material for organic EL may be used. While specific compounds thereof will be illustrated below, the present embodiment is not limited to these materials.

The acceptor material may include an inorganic material such as Au, Pt, W, Ir, POCl₃, AsF₆, Cl, Br, I, vanadium oxide (V₂O₅), or molybdenum oxide (MoO₂), or an organic material such as a compound having a cyano group such as TCNQ (7,7,8,8,-tetracyanoquinodimethane), TCNQF4 (tetrafluorotetracyanoquinodimethane), TCNE (tetracyanoethylene), HCNB (hexacyanobutadiene) or DDQ (dicyclodicyanobenzoquinone), a compound having a nitro group such as TNF (trinitrofluorenone) or DNF (dinitrofluorenone), fluoranil, chloranil or bromanil. Among these, the compound having a cyano group such as TCNQ, TCNQF4, TCNE, HCNB, or DDQ is more preferred since the compound can effectively increase a carrier concentration.

As the electron blocking layer, the same layer as those described above as the hole transport layer 13 and the hole injection layer may be used.

Examples of the electron injection and electron transport material may include an inorganic material that is an n-type semiconductor, a low-molecular-weight material such as an oxadiazole derivative, a triazole derivative, a thiopyrazinedioxide derivative, a benzoquinone derivative, a naphthoquinone derivative, an anthraquinone derivative, a diphenoquinone derivative, a fluorenone derivative, or a benzodifuran derivative, and a polymer material such as poly(oxadiazole) (Poly-OXZ) or a polystyrene derivative (PSS). In particular, the electron injection material may include, particularly, a fluoride such as lithium fluoride (LiF) or barium fluoride (BaF₂), and an oxide such as lithium oxide (Li₂O).

In terms of more efficient injection and transport of electrons from the cathode, it is preferable to use, as the material used as the electron injection layer, a material whose energy level of lowest unoccupied molecular orbital (LUMO) is higher than that of an electron injection and transport material used for the electron transport layer. It is preferable to use, as the material used as the electron transport layer, a material whose electron mobility is higher than that of the electron injection and transport material used for the electron injection layer.

Further, it is preferable to dope the electron injection and transport material with donors in order to further improve injection and transport of electrons. As the donors, a known donor material for organic EL may be used. While specific compounds thereof will be illustrated below, the present embodiment is not limited to these materials.

As the donor material, there are an inorganic material, such as an alkali metal, an alkaline ground metal, a rare earth element, Al, Ag, Cu or In, and an organic material, such as a compound having an aromatic tertiary amine as a backbone such as aniline, phenylenediamine, benzidines (N,N,N′,N′-tetra phenyl benzidine, N,N′-bis-(3-methylphenyl)-N,N′-bis-(phenyl)-benzidine, N,N′-di(naphthalene-1-yl)-N,N′-diphenyl-benzidine, etc.), triphenylamines (triphenylamine, 4,4′,4″-tris(N,N-diphenyl-amino)-triphenylamine, 4,4′,4″-tris(N-3-methyl-phenyl-N-phenyl-amino)-triphenylamine, 4,4′,4″-tris(N-(1-naphthyl)-N-phenyl-amino)-triphenylamine, etc.), tri-phenyl diamine(N,N′-di-(4-methyl-phenyl)-N,N′-diphenyl-1,4-phenylenediamine), a condensed polycyclic compound such as phenanthrene, pyrene, perylene, anthracene, tetracene, and pentacene (however, the condensed polycyclic compound may have a substituent group), TTF (tetrathiafulvalene), dibenzofuran, phenothiazine, or carbazole.

Particularly, the compound having an aromatic tertiary amine as a skeleton, the condensed polycyclic compound, and the alkali metal are more preferred because they more effectively increase a carrier concentration.

The organic EL layer 17 such as the light emitting layer 14, the hole transport layer 13, the electron transport layer 15, the hole injection layer and the electron injection layer may be formed using a coating liquid for forming the organic EL layer in which the above material is dispersed and dissolved in a solvent, through a known wet process based on a coating method, such as a spin coating method, a dipping method, a doctor blade method, a discharge coating method, or a spray coating method, or a printing method such as an inkjet method, a relief printing method, an intaglio printing method, a screen printing method, or a micro gravure coating method, a known dry process such as a resistance heating deposition method, an electron beam (EB) deposition method, a molecular beam epitaxy (MBE) method, a sputtering method, or an organic vapor phase deposition (OVPD) method, a laser transfer method, or the like. Further, when the organic EL layer is formed by the wet process, the coating liquid for forming the organic EL layer may include an additive agent for adjusting physical properties of a coating liquid such as a leveling agent or a viscosity modifier.

A film thickness of each layer constituting the organic EL layer 17 is typically about 1 nm to 1000 nm, but is more preferably 10 nm to 200 nm. If the film thickness of each layer constituting the organic EL layer 17 is less than 10 nm, originally required physical properties (an injection property, a transport property, and a confinement property of charges (electrons and holes)) are likely not to be obtained. Further, pixel abnormality may occur due to foreign matter such as dust.

Further, when the film thickness of each layer constituting the organic EL layer 17 exceeds 200 nm, a driving voltage may increase, leading to an increase in power consumption.

### 5-2. First Electrode and Second Electrode

A known electrode material may be used as an electrode material for forming the first electrode 12 and the second electrode 16. The first electrode 12 and the second electrode 16 function, as a pair, as an anode or a cathode of the fluorescent display device 20. In other words, when the first electrode 12 is the anode, the second electrode 16 is the cathode, and when the first electrode 12 is the cathode, the second electrode 16 is the anode. While a concrete compound and a forming method will be described below, the present embodiment is not limited to such a material and forming method.

A material in a case in which the first electrode 12 that is the anode is formed may include a metal such as gold (Au), platinum (Pt) or nickel (Ni) having a work function of 4.5 eV or more, an oxide (ITO) containing indium (In) and tin (Sn), an oxide (SnO₂) of tin (Sn), a compound (IZO) containing indium (In) and zinc (Zn), and the like, from the viewpoint of more efficient injection of holes into the organic EL layer 17. Further, an electrode material for forming the second electrode 16 that is the cathode may include a metal such as lithium (Li), calcium (Ca), cerium (Ce), barium (Ba) or aluminum (Al) having a work function of 4.5 eV or less, or an alloy such as an Mg:Ag or Li:Al alloy containing such a metal, from the viewpoint of more efficient injection of electrons into the organic EL layer 17.

The first electrode 12 and the second electrode 16 may be formed by a known method such as an EB (electron beam) deposition method, a sputtering method, an ion plating method, or a resistance heating vapor deposition method using the above material, but the present embodiment is not limited to such a forming method. Further, the formed electrode may be patterned by a photolithography method or a laser ablation method, as necessary, or an electrode patterned directly through a combination with a shadow mask may be formed.

Thicknesses of the first electrode 12 and the second electrode 16 are preferably 50 nm or more. When the thicknesses of the first electrode 12 and the second electrode 16 are less than 50 nm, wiring resistance increases. Accordingly, a driving voltage is likely to increase.

In the fluorescent display device 20 of the present embodiment, since the light emitted from the light emitting layer 14 of the organic EL element 10, which is the light source, is extracted from the second electrode 16 side, which is each fluorescent layer 8R, 8G, or 8B side, it is preferable to use a semi-transparent electrode as the second electrode 16. A single semi-transparent electrode of a metal or a combination of a semi-transparent electrode of a metal and a transparent electrode material may be used as a material of the semi-transparent electrode, but silver is preferred from the viewpoint of transmittance and reflectance. A film thickness of the semi-transparent electrode is preferably 5 nm to 30 nm. When the film thickness of the semi-transparent electrode is less than 5 nm, reflection of light is likely not to be sufficiently performed and the effect of the interference is likely not to be sufficiently obtained when a microcavity effect that will be described below is used. Further, when the film thickness of the semi-transparent electrode exceeds 30 nm, the transmittance of light rapidly decreases. Accordingly, luminance and efficiency are likely to be degraded.

In the fluorescent display device 20 of the present embodiment, it is preferable to use an electrode (a reflecting electrode) whose reflectance of light is high, as the first electrode 12 located on the side opposite the side from which the light emitted from the light emitting layer 14 of the organic EL element 10, which is the light source, is extracted in order to increase extraction efficiency of the light emitted from the light emitting layer 14. Examples of the electrode material used in this case may include a reflective metal electrode such as aluminum, silver, gold, an aluminum-lithium alloy, an aluminum-neodymium alloy or an aluminum-silicon alloy, or an electrode that is a combination of a transparent electrode and a reflective metal electrode (the reflecting electrode). Further, an example in which the first electrode 12, which is the transparent electrode, is formed on the planarizing film 4 via the reflecting electrode 11 is illustrated in FIG. 1.

### 5-3. Edge Cover

Further, in the fluorescent display device 20 of the present embodiment, a plurality of first electrodes 12 located on the substrate 1 side (the side opposite the side from which the light emitted from the light emitting layer 14 is extracted) are arranged in parallel to correspond to respective pixels (the fluorescent layers 8R, 8G and 8B). Further, an edge cover 19 is formed of an insulating material to cover each edge portion (end portion) of the first adjacent electrode 12.

This edge cover 19 is provided to individually partition the plurality of first electrodes 12 formed to correspond to the pixel formation area and separate the first adjacent electrodes 12 in an insulating manner. Further, the edge cover 19 is provided for the purpose of preventing leakage of current from occurring between the first electrode 12 located on the periphery side of the pixel formation area and a portion of the second electrode 16 adjacent to the first electrode 12.

That is, a vertical conductor portion 16A is formed so that leakage of current does not occur between the second electrode 16 and the first electrode 12 adjacent thereto in the peripheral portion of the pixel formation area of the second electrode 16 provided to surround the organic EL layer 17, which includes the hole transport layer 13, the light emitting layer 14 and the electron transport layer 15. The vertical conductor portion 16A passes through the edge cover 19, the planarizing film 4 and the interlayer insulating film 3 to be conducted with a portion of the TFT circuit 2. The edge cover 19 may be formed by a known method such as an EB (Electron Beam) deposition method, a sputtering method, an ion plating method, or a resistance heating deposition method using an insulating material and patterned by a photolithography method of a known dry or wet method, but the present invention is not limited to such a forming method. Further, a conventional known material may be used as an insulating material layer constituting the edge cover 19, and the insulating material layer is not particularly limited in the present embodiment. The insulating material layer constituting the edge cover 19 needs to transmit light and an example thereof may include, SiO, SiON, SiN, SiOC, SiC, HfSiON, ZrO, HfO, LaO or the like.

A film thickness of the edge cover 19 is preferably 100 nm to 2000 nm. It is possible to maintain sufficient insulation, prevent leakage between the first electrode 12 and the second electrode 16, and prevent an increase in power consumption and non-emission from occurring by setting the film thickness of the edge cover 19 to 100 nm or more. Further, it is possible to prevent reduction of productivity of a film formation process and a disconnection of the second electrode 16 in the edge cover 19 from occurring by setting the thickness of the edge cover 19 to 2000 nm or less. Conversely, if the film thickness is 100 nm or less, insulation is not sufficient, leakage between the first electrode 12 and second electrode 16 may occur, and an increase in power consumption and non-emission are easily caused. Further, if the film thickness is 2000 nm or more, the film formation process takes time, and degradation of productivity and a disconnection of the electrode in the edge cover 19 may be caused.

### 6. Sealing Film and Sealing Substrate

In the present embodiment, an inorganic sealing film 5 is formed of SiO, SiON, SiN or the like to cover upper and side surfaces of the organic EL element 10. The inorganic sealing film 5 may be formed by forming an inorganic film such as SiO, SiON or SiN by a plasma CVD method, an ion plating method, an ion beam method, a sputtering method or the like. Further, the inorganic sealing film 5 need to be optically transparent since light is extracted from the second electrode 16 side of the organic EL element 10. Further, the sealing substrate 9 is arranged on the organic EL element 10 whose upper and side surfaces have been covered with the inorganic sealing film 5, so that each of the fluorescent layers 8R, 8G and 8B opposes the organic EL element 10. The red fluorescent layers 8R, the green fluorescent layer 8G and the blue fluorescent layer 8B divided by the black matrix 7 and arranged in parallel are formed on one surface of the sealing substrate 9. The sealing material 6 is sealed between the inorganic sealing film 5 and the sealing substrate 9. That is, the red fluorescent layer 8R, the green fluorescent layer 8G, and the blue fluorescent layer 8B arranged opposite the organic EL element 10 are surrounded and partitioned by the black matrix 7 and sealed in the sealing area surrounded by the sealing material 6.

Further, the sealing film 5 and the sealing substrate 9 may be formed by a known sealing material and sealing method, unlike the above description. Specifically, the method may include a method of sealing an inert gas such as nitrogen gas or argon gas with glass, metal or the like. Further, it is preferable for a moisture absorbent such as barium oxide to be mixed in the sealed inert gas since deterioration of the organic EL layer 17 can be effectively reduced.

Further, a resin may be applied or bonded to the second electrode 16 using a spin coating method, ODF, or a laminating method and may be used as the sealing film 5. With the sealing film 5, it is possible to prevent oxygen and moisture from being mixed from the outside into the element and improve a lifespan of the organic EL element. Further, the present embodiment is not limited to such a member or forming method.

The same substrate as the substrate 1 may be used as the sealing substrate 9, but in the fluorescent display device 20 of the present embodiment, since the emitted light is extracted from the sealing substrate 9 side (an observer observes the display caused by the emitted light from the outer side of the sealing substrate 9), it is necessary to use a light-transmissive material as the sealing substrate 9.

### 7. Fluorescent Layer

The fluorescent layer of the present embodiment includes the red fluorescent layer 8R, the green fluorescent layer 8G and the blue fluorescent layer 8B provided on the light extraction side of the organic EL element 10. The red fluorescent layer 8R absorbs ultraviolet blue light emitted from the organic EL element 10 and emits red light. The green fluorescent layer 8G absorbs ultraviolet blue light emitted from the organic EL element 10 and emits green light. The blue fluorescent layer 8B absorbs ultraviolet blue light emitted from the organic EL element 10 and emits blue light. Further, when a material allowing emitted light whose blue color purity is high in the ultraviolet blue light emitted from the organic EL element 10 to be obtained is used, the blue fluorescent layer 8B can be formed of a material that transmits the blue light emitted from the organic EL element 10 as it is. Further, when the material allowing emitted light whose blue color purity is high in the ultraviolet blue light emitted from the organic EL element 10 to be obtained is used, the blue fluorescent layer 8B itself may constitute a blue color filter.

The fluorescent layer may be formed of only a fluorescent material that will be illustrated below or may optionally contain an additive agent or the like. Further, the fluorescent layer may have a configuration in which these materials may be dispersed in a polymer material (a binding resin) or an inorganic material.

Further, it is preferable to form the black matrix 7 illustrated in FIG. 1A between the fluorescent layers adjacent in a surface direction.

A known fluorescent material may be used as a constituent material of the fluorescent layer used in the present embodiment. Such a fluorescent material is classified as an organic fluorescent material or an inorganic fluorescent material, and a specific compound of the materials will be illustrated below, but the present embodiment is not limited to such materials.

For the organic fluorescent material used in the present embodiment, a fluorochrome that converts ultraviolet excitation light into emitted blue light may include a styrylbenzene-based dye: 1,4-bis(2-methylstyryl)benzene, trans-4,4′-diphenylstyrylbenzene, a coumarin-based dye: 7-hydroxy-4-methylcoumarin, or the like.

Further, a fluorochrome that converts the ultraviolet blue excitation light into emitted green light may include a coumarin-based dye: 2,3,5,6-1H, 4H-tetrahydro-8-trifluoromethylquinolizine(9,9a,1-gh)coumarin (coumarin 153), 3-(2′-benzothiazolyl)-7-diethylaminocoumarin (coumarin 6), 3-(2′-benzimidazolyl)-7-N,N-diethylaminocoumarin (coumarin 7), a naphthalimide-based dye: basic yellow 51, solvent yellow 11, solvent yellow 116, or the like.

Further, a fluorochrome that converts ultraviolet blue excitation light into emitted red light may include a cyanine-based dye: 4-dicyanomethylene-2-methyl-6-(p-dimethylaminostillyl)-4H-pyran, a pyridine-based dye: 1-ethyl-2-[4-(p-dimethylaminophenyl)-1,3-butadienyl]-pyridinium-perchlorate, a rhodamine-based dye: rhodamine B, rhodamine 6G, rhodamine 3B, rhodamine 101, rhodamine 110, basic violet 11, and sulforhodamine 101, or the like.

Further, for the inorganic fluorescent material, a fluorescent material that converts ultraviolet excitation light into emitted blue light may include Sr₂P₂O₇: Sn⁴⁺, Sr₄Al₁₄O₂₅: Eu²⁺, BaMgAl₁₀O₁₇: Eu²⁺, SrGa₂S4: Ce³⁺, CaGa₂S₄: Ce³⁺, (Ba, Sr)(Mg, Mn)Al₁₀O₁₇: Eu²⁺, (Sr, Ca, Ba₂, 0Mg)₁₀ (PO₄)₆Cl₂: Eu²⁺, BaAl₂SiO₈: Eu²⁺, Sr₂P₂O₇: Eu²⁺, Sr₅(PO4)₃Cl: Eu²⁺, (Sr, Ca, Ba) 5 (PO₄)₃Cl: Eu²⁺, BaMg₂Al₁₆O₂₇: Eu²⁺, (Ba, Ca)₅(PO₄)₃Cl: Eu²⁺, Ba₃MgSi₂O₈: Eu²⁺, Sr₃MgSi₂O₈: Eu²⁺, or the like.

Further, a fluorescent material that converts ultraviolet blue excitation light into emitted green light may include (BaMg)Al₁₆O₂₇: Eu²⁺, Mn²⁺, Sr₄Al₁₄O₂₅: Eu²⁺, (SrBa)Al₁₂Si₂O₈: Eu²⁺, (BaMg)₂SiO₄: Eu²⁺, Y₂SiO₅: Ce³⁺, Tb³⁺, Sr₂P₂O₇—Sr₂B₂O₅: Eu²⁺, (BaCaMg)₅ (PO₄)₃Cl: Eu²⁺, Sr₂Si₃O₈—2SrCl₂: Eu²⁺, Zr₂SiO₄, MgA₁₁O₁₉: Ce³⁺, Tb³⁺, Ba₂SiO₄: Eu²⁺, Sr₂SiO₄: Eu²⁺, (BaSr) SiO₄: Eu²⁺, or the like. Further, a fluorescent material that converts ultraviolet blue excitation light into emitted red light may include Y₂O₂S,: Eu³⁺, YAlO₃: Eu³⁺, Ca₂Y₂(SiO₄)₆: Eu³⁺, LiY₉(SiO₄)₆O₂: Eu³⁺, YVO₄: Eu³⁺, CaS: Eu³⁺, Gd₂O₃: Eu³⁺, Gd₂O₂S: Eu³⁺, Y(P,V)O₄: Eu³⁺, Mg₄GeO_{5.5}F: Mn⁴⁺, Mg₄GeO₆: Mn⁴⁺, K₅Eu_{2.5}(WO₄)_{6.25}, Na₅Eu_{2.5}(WO₄)_{6.25}, K₅Eu_{2.5}(MoO₄)_{6.25}, Na₅Eu_{2.5}(MoO₄)_{6.25} or the like.

The red fluorescent layer 8R, the green fluorescent layer 8G and the blue fluorescent layer 8B can be obtained by using the inorganic or organic fluorescent material that converts emitted light into red, green and blue light as described above. Further, the ultraviolet blue light emitted by the organic EL element 10 can be converted into each color and emitted to the outside by the red fluorescent layer 8R, the green fluorescent layer 8G, and the blue fluorescent layer 8B. Further, in the present embodiment, since the ultraviolet blue light is emitted from the organic EL layer 17, the blue fluorescent layer 8B may be buried with a coating type transparent resin layer or buried with a blue color-based coating type resin layer. The blue fluorescent layer 8B may be substituted by such a resin layer, but it is to be understood that a fluorescent layer formed of a fluorescent material that converts the ultraviolet excitation light into emitted blue light as described above may be used.

Further, the inorganic fluorescent material may be subjected to surface modification treatment, as necessary. A method of the surface modification treatment may include a method based on chemical treatment using a silane coupling agent, a method based on a physical treatment using addition of fine particles on a sub-micron level, and a method based on a combination thereof. Considering stability for deterioration caused by the excitation light and deterioration caused by emitted light, it is preferable to use an inorganic material. Further, when the inorganic material is used, an average particle diameter (d50) is preferably 1 μm to 50 μm. If the average particle diameter is 1 μm or less, the luminous efficiency of the fluorescent material rapidly decreases. Further, if the average particle diameter is 50 μm or more, it becomes very difficult to form a flat film and depletion between the fluorescent layer and the organic EL element is generated (depletion (refractive index: 1.0) between the organic EL element (refractive index: about 1.7) and the inorganic fluorescent layer (refractive index: about 2.3)). Accordingly, the light from the organic EL element does not efficiently reach the inorganic fluorescent layer, resulting in degradation in luminous efficiency of the fluorescent layer.

Further, patterning is enabled by a photolithography method by using a photosensitive resin as the polymer resin.

Here, as the photosensitive resin, a kind of photosensitive resin having a reactive vinyl group (a photocurable resist material) such as an acrylic acid-based resin, a methacrylic acid-based resin, a polyvinyl cinnamate-based resin or a hard rubber-based resin, or a mixture of plural kinds of photosensitive resins may be used.

Further, the fluorescent layer may be formed using a coating liquid for forming a fluorescent layer in which the fluorescent material and the resin material are dissolved and dispersed in a solvent by a known wet process such as a coating method, for example, a spin coating method, a dipping method, a doctor blade method, a discharge coating method, or a spray coating method, and a printing method such as an inkjet method, a relief printing method, an intaglio printing method, a screen printing method, or a micro gravure coating method. The fluorescent layer may be formed by a known dry process such as a resistance heating deposition method, an electron beam (EB) deposition method, a molecular beam epitaxy (MBE) method, a sputtering method, and an organic vapor phase deposition (OVPD) method, a laser transfer method using the above material.

A film thickness of the fluorescent material described above, typically, is about 100 nm to 100 μm, but 1 μm to 100 μm is preferred. If the film thickness is less than 100 nm, it is not possible to sufficiently absorb the blue light emitted from the organic EL layer 17. Accordingly, the luminous efficiency is degraded and color purity is degraded due to mixing of the transmitted blue light with a necessary color. The film thickness is preferably 1 μm or more to increase absorption of the light emitted from the organic EL layer 17 and reduce the transmitted blue light to the extent that the color purity is not reduced. Moreover, if the film thickness exceeds 100 μm, the blue light emitted from the organic EL layer 17 is already sufficiently absorbed, and there is no increase in the luminous efficiency but an increase in material cost due to material consumption.

Further, it is preferable to planarize the fluorescent layers 8R, 8G and 8B using the planarizing film or the like. Accordingly, it is possible to prevent the depletion between the organic EL layer 17 and the fluorescent layer. Further, it is possible to increase adhesion of the organic EL element substrate and the fluorescent layer substrate.

### 8. Conductive Layer

In the fluorescent display device 20 of the present embodiment, the transparent conductive layer (the conductor) 18 is stacked to correspond to at least the pixel area in which the fluorescent layers 8R, 8G and 8B are arranged on the outer surface of the sealing substrate 9. That is, the conductive layer 18 is formed on a different surface from the surface of the sealing substrate 9 on which the fluorescent layers 8R, 8G and 8B have been formed. The conductive layer 18 overlaps the pixel area.

This conductive layer 18 is preferably formed as a thin film having an antistatic function and optical transparency. As an example of the conductive layer 18, it is preferable for the conductive layer 18 to be formed as a thin film having electrical conductivity. Alternatively, it is preferable for the conductive layer 18 to be formed as a thin film that has electrical conductivity by dispersing a required amount of conductive particles inside a transparent resin thin film. Further, in the configuration of FIG. 1A, an example in which the conductive layer 18 is coated on the entire upper surface of the sealing substrate 9 is shown. ITO, SnO₂, In₂O₃, ZnO, IGZO, βGa₂O₃, TeO₂, GeO₂, WO₃, MoO₃, CuAlO₂, CuGaO₂, CuInO₂ or the like may be used as a material of the conductive thin film or the conductive particles for antistatic electricity in consideration of optical transparency.

Further, considering that the conductive layer 18 may be a metal or may be an ultra-thin film of several nm to tens of nm, the conductive layer 18 may be formed of, for example, Au, Ag, Al, Pt, Cu, Mn, Mg, Ca, Li, Yb, Eu, Sr, Ba or Na, or an alloy of two or more metals appropriately selected from among these metals, specifically, Mg:Ag, Al:Li, Al:Ca or Mg:Li. Moreover, even when the thin film is formed of a carbon-based compound represented by fullerene, carbon nanotube, or graphene, the conductive layer 18 has an antistatic effect since the thin film has excellent electrical conductivity.

However, the present embodiment is not limited thereto.

Further, when the conductive particles are used, the conductive particles may be transparent conductive particles or metal particles. Further, the conductive particles may not necessarily be in a spherical shape, but may be in a spheroidal shape, a circular columnar shape, a polygonal columnar shape, or an asymmetric shape.

It was found from the study of the present inventor that there is an effect even when a film thickness of the conductive layer 18 that is effective for antistatic electricity is 1 nm. A film of the conductive layer having a film thickness of 1 nm or more is more effective. Further, sheet resistance of the ITO corresponding to such a film thickness is 2×10³Ω/□ or less. Accordingly, it is effective in terms of an antistatic effect for the sheet resistance of the conductive film to be 2×10³Ω/□ or less.

### 9. Color Filter

In the fluorescent display device 20 of the present embodiment, it is preferable to provide a color filter between the substrate 9 on the light extraction side and the fluorescent layers 8R, 8G and 8B. As the color filter, a conventional color filter may be used. Here, it is possible to improve color purity of red, green and blue pixels and expand a color reproduction range of the fluorescent display device 20 by providing the color filter. Further, a red color filter formed on the red fluorescent layer 8R and a green color filter formed on the green fluorescent layer 8G absorb a blue component and an ultraviolet component of the external light. Accordingly, it is possible to reduce or prevent emission of the fluorescent layer caused by external light and to reduce or prevent degradation of the contrast.

### 10. Polarizing Plate

It is preferable to provide a polarizing plate on the light extraction side in the fluorescent display device 20 of the present embodiment. As the polarizing plate, a combination of a conventional linear polarization plate and a λ/4 plate may be used. Here, it is possible to prevent reflection of external light from the electrode, prevent reflection of the external light on the surface of the substrate 1 or the sealing substrate 9, and improve contrast of the fluorescent display device 20 by providing the polarizing plate.

The fluorescent display device 20 configured as described above includes the conductive layer 18 having optical transparency on the sealing substrate 9 at a distance from the light emitting layer 14 among the substrates of the fluorescent display device 20, i.e., the sealing substrate 9 on the observer side. The conductive layer 18 is arranged to overlap the pixel formation area. In the fluorescent display device 20, the conductive layer 18 has a shielding function against external static electricity or the like.

Further, in the present embodiment, the conductive layer 18 is formed on the surface (the outer surface) of the sealing substrate 9 opposite the light emitting layer. Accordingly, an electric field from the second electrode 16, which is the anode of the current injection electrode, is fully terminated at the second electrode 16, which is the cathode, rather than the conductive layer 18. Accordingly, the conductive layer 18 does not adversely affect display quality. A thickness of the light emitting layer 14 and a distance between the anode of the current injection electrode and the cathode are about tens of nm to several μm while a thickness of the transparent sealing substrate 9 is about 0.1 mm to 1 mm. This is because there is a difference in the order of tens to hundreds.

Accordingly, it is possible to prevent the occurrence of abnormality of the display even in the case in which a high potential of external static electricity or the like on the surface of the fluorescent display device 20 is applied.

### Second Embodiment

FIG. 2 is a schematic cross-sectional view illustrating an organic light emitting device according to a second embodiment of the present invention.

In a fluorescent display device 30 as an example of the organic light emitting device illustrated in FIG. 2, the same components as the fluorescent display device 20 of the first embodiment described above are denoted by the same reference numerals and a description thereof will be omitted. Each component illustrated in FIG. 2 will be briefly described.

The fluorescent display device 30 of the present embodiment has a configuration in which the conductive layer 18 provided on the outer surface of the sealing substrate 9 in the configuration of the fluorescent display device 20 of the first embodiment is omitted, and instead, a conductive layer (a conductor) 31 is provided between fluorescent layers 8R, 8G and 8B and a sealing substrate 9.

A configuration of the conductive layer 31 may be the same as that of the conductive layer 18 of the first embodiment.

The fluorescent display device 30 having the configuration illustrated in FIG. 2 is capable of the same display as the fluorescent display device 20 of the first embodiment described previously and of obtaining the same operation and effects as an antistatic function. Further, when the structure illustrated in FIG. 2 and the structure illustrated in FIG. 1 are compared in terms of the antistatic function, the structure illustrated in FIG. 2 has an effect such that display abnormality of the organic EL layer 17 against external static electricity can be efficiently suppressed since the conductive layer 31 is provided inward from the sealing substrate 9, i.e., on the side close to the organic EL layer 17.

Further, the structure of FIG. 2 can provide a function of improving light extraction efficiency specific to the organic light emitting device, in addition to the antistatic purpose. The fluorescent layers 8R, 8G and 8B are scattering bodies as long as an inorganic fluorescent material is used. Accordingly, the light is scattered and does not necessarily travel in a forward direction. With the structure of FIG. 2, it is possible to provide an effect of reducing a total reflection component at an interface and improve the light extraction efficiency by setting a refractive index of the conductive layer 31 for an antistatic purpose to a value between a refractive index of the glass substrate 9 and a refractive index of the fluorescent layers 8R, 8G and 8B.

### Third Embodiment

FIG. 3 is a schematic cross-sectional view illustrating an organic light emitting device according to a third embodiment of the present invention.

In a fluorescent display device 40 as an example of the organic light emitting device illustrated in FIG. 3, the same components as the fluorescent display device 20 of the first embodiment described above are denoted by the same reference numerals and a description thereof will be omitted. Each component illustrated in FIG. 3 will be briefly described.

The fluorescent display device 40 of the present embodiment has a configuration in which the conductive layer 18 provided on the outer surface of the sealing substrate 9 in the configuration of the fluorescent display device 20 of the first embodiment is omitted, and instead, fluorescent layers 8R, 8G and 8B themselves have electrical conductivity.

In this embodiment, conductive particles such as metal particles are dispersed in each of the fluorescent layers 8R, 8G and 8B to provide each of the fluorescent layers 8R, 8G and 8B with electrical conductivity. For example, a configuration in which metal particles (conductive particles; conductor) 8a such as Au particles are dispersed in the fluorescent layer 8R, metal particles (conductive particles; conductor) 8b such as Ag particles are dispersed in the fluorescent layer 8G, and metal particles (conductive particles; conductor) 8a such as Al particles are dispersed in the fluorescent layer 8G may be adopted. As the conductive particles dispersed in the respective fluorescent layers 8R, 8G and 8B, different particles may be individually used or conductive particles of the same types of materials may be used.

Further, if the conductive particles are used, the conductive particles may be transparent conductive particles or may be metal particles. The conductive particles may not necessarily be in a spherical shape, and may be in a spheroidal shape, a circular columnar shape, a polygonal columnar shape, or an asymmetric shape.

The fluorescent display device 40 having the configuration illustrated in FIG. 3 is capable of the same display as the fluorescent display device 20 of the first embodiment described previously and obtaining the same operation and effects as the antistatic function.

Further, a coupling with the fluorescent light emission occurs due to an action of surface plasmons excited on a metal particle surface even when the metal particles such as Ag, Al, and Au are dispersed in the respective fluorescent layers 8R, 8G and 8B, and thus there is an effect such that light intensity can be improved.

In the structure of FIG. 3, it is possible to provide a function of improving light extraction efficiency specific to the organic light emitting device, in addition to the antistatic purpose. In the structure of FIG. 3, it is possible to enhance the light of the fluorescent material and obtain a bright fluorescent display device 40 by adjusting sizes and shapes of the metal particles 8a, 8b and 8c so that plasmon resonance frequencies match according to colors of the fluorescent layers 8R, 8G and 8B.

In the structure of FIG. 3, if the optical enhancement effect resulting from the plasmon effect is provided as described above, for example, a type, a size and a shape of a metal allowing the plasma resonance frequency to be located in a red area is effective in the red fluorescent layers 8R. In the green fluorescent layer 8G, a type, a size and a shape of a metal according to a green area is required. However, while any metal, any type, and any shape may be used only for an antistatic effect, it is preferable to aim at effects further including the optical enhancement effect using the plasmon effect. In the case of this structure, a ground is not required. It is certain that there is a certain degree of antistatic effect without the ground. Rather, an effect of a gain resulting from the optical enhancement effect is great.

### Fourth Embodiment

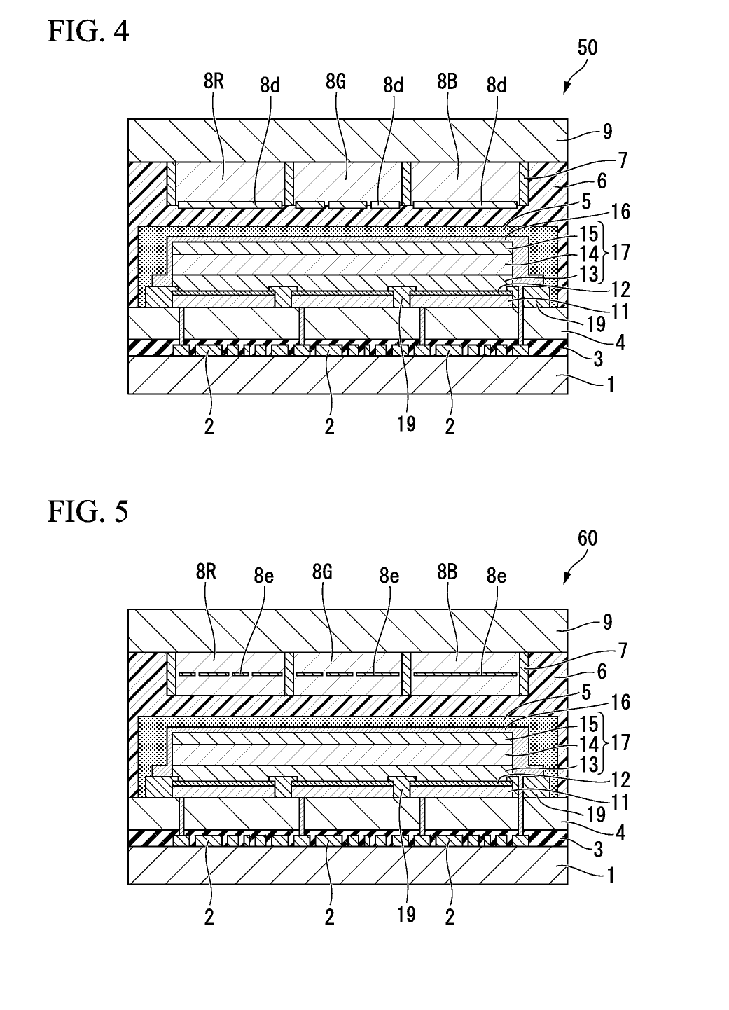

FIG. 4 is a schematic cross-sectional view illustrating an organic light emitting device according to a fourth embodiment of the present invention.

In a fluorescent display device 50 as an example of the organic light emitting device illustrated in FIG. 4, the same components as the fluorescent display device 20 of the first embodiment described above are denoted by the same reference numerals, and a description thereof will be omitted. Each component illustrated in FIG. 4 will be briefly described.

The fluorescent display device 50 of the present embodiment has a configuration in which the conductive layer 18 provided on the outer surface of the sealing substrate 9 in the configuration of the fluorescent display device 20 of the first embodiment is omitted, and instead, a conductive layer (a conductor) 8d formed as a thin metal film is provided in inner bottoms of fluorescent layers 8R, 8G and 8B. That is, the conductive layer (the conductor) 8d formed as a thin metal film is provided on a surface of the fluorescent layers 8R, 8G and 8B close to a light emitting layer 14.

The conductive layer 8d includes, for example, a thin film of an excellent conductivity metal such as Ag, Au or Pt. The conductive layer 8d is formed as a very thin film having a thick thickness of about 1 nm to 10 nm. With such a film thickness, when the conductive layer 8d is the thin metal film, the conductive layer 8d is highly light-transmissive. Further, even when the conductive layer 8d is the thin metal film, the conductive layer 8d is not an obstacle when light emitted from the organic EL element 10 is caused to reach the fluorescent layers 8R, 8G and 8B. Further, the very thin conductive layer 8d may not have a uniform thickness as a thin film or may be an uneven film. Even when the conductive layer 8d has a partial island shape and includes a portion in which the film is not connected, the conductive layer 8d functions as the conductive film for an antistatic purpose with no problem.

The fluorescent display device 50 having the configuration illustrated in FIG. 4 is capable of the same display as the fluorescent display device 20 of the first embodiment described previously and obtaining the same operation and effects as the antistatic function. Further, when the structure illustrated in FIG. 4 and the structure illustrated in FIG. 1 are compared in terms of charging, the structure illustrated in FIG. 4 has a high shielding function against external static electricity or the like and achieves an effect such that display abnormality can be effectively suppressed. Further, if the conductive layer 8d is formed in each of the fluorescent layers 8R, 8G and 8B, coupling with fluorescent light emission occurs due to the action of surface plasmons excited on the surface of the conductive layer 8d of a metal, and thus there is an effect such that light intensity can be improved.

In the structure of FIG. 4, scattered light can be reflected by the antistatic layer 8d and reused, in addition to the antistatic purpose, thereby providing a bright fluorescent display device 50.

### Fifth Embodiment

FIG. 5 is a schematic cross-sectional view illustrating an organic light emitting device according to a fifth embodiment of the present invention.

In a fluorescent display device 60 as an example of the organic light emitting device illustrated in FIG. 5, the same components as the fluorescent display device 20 of the first embodiment described above are denoted by the same reference numerals, and a description thereof will be omitted. Each component illustrated in FIG. 5 will be briefly described.

The fluorescent display device 60 of the present embodiment has a configuration in which the conductive layer 18 provided on the outer surface of the sealing substrate 9 in the configuration of the fluorescent display device 20 of the first embodiment is omitted, and instead, a conductive layer 8e (a conductor) formed as a thin metal film is provided in a central portion in a thickness direction of fluorescent layers 8R, 8G and 8B, such that the fluorescent layer is vertically divided in two via the conductive layer 8e.

The conductive layer 8e is formed as, for example, a thin film of an excellent conductivity metal such as Ag, Au or Pt. The conductive layer 8e is formed as a very thin film having a thin thickness of about 1 nm to 10 nm. With this film thickness, the conductive layer 8e is highly light-transmissive and is not an obstacle when light emitted from the organic EL element 10 reaches the upper portion of the fluorescent layers 8R, 8G and 8B via the conductive layer 8e. Further, the very thin conductive layer 8e may not have a uniform thickness as a film or may be an uneven film. Even when the conductive layer 8e has a partial island shape and includes a portion in which the conductive film is not connected, the conductive layer 8e functions as the conductive film for an antistatic purpose with no problem.

The conductive layer 8e in this case may be a thin metal film or may have a structure in which particles are densely arranged. Further, the metal particles constituting the thin metal film may not necessarily be in a spherical shape, and may be in a spheroidal shape, a circular columnar shape, a polygonal columnar shape or an asymmetric shape.

The fluorescent display device 60 having the configuration illustrated in FIG. 5 is capable of the same display as the fluorescent display device 20 of the first embodiment described previously and obtaining the same operation and effects as the antistatic function. Further, if the structure illustrated in FIG. 5 and the structure illustrated in FIG. 1 are compared in terms of antistatic electricity, the structure illustrated in FIG. 5 has a high shielding function against external static electricity or the like and has an effect such that display abnormality can be efficiently suppressed since the conductive layer 8e is arranged at a position close to the organic EL element 10. Further, if the conductive layer 8e is formed in each of the fluorescent layers 8R, 8G and 8B, coupling with the fluorescent light emission occurs due to an action of surface plasmons excited on the surface of the conductive layer 8e of a metal, and thus there is an effect such that light intensity can be improved.

In the structure of FIG. 5, it is possible to enhance the light of the fluorescent material and reflect and reuse scattered light using the conductive layer 8e by adjusting the size and the shape of the conductive layer 8e so that plasmon resonance frequencies match according to colors of the fluorescent layers 8R, 8G and 8B, in addition to the antistatic purpose using the conductive layer (the conductor) 8e, thereby obtaining a brighter fluorescent display device 60.

### Sixth Embodiment

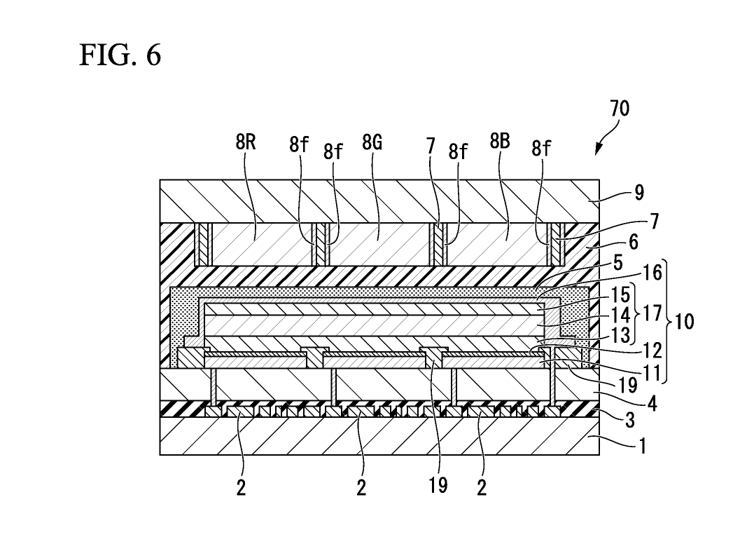

FIG. 6 is a schematic cross-sectional view illustrating an organic light emitting device according to a sixth embodiment of the present invention.

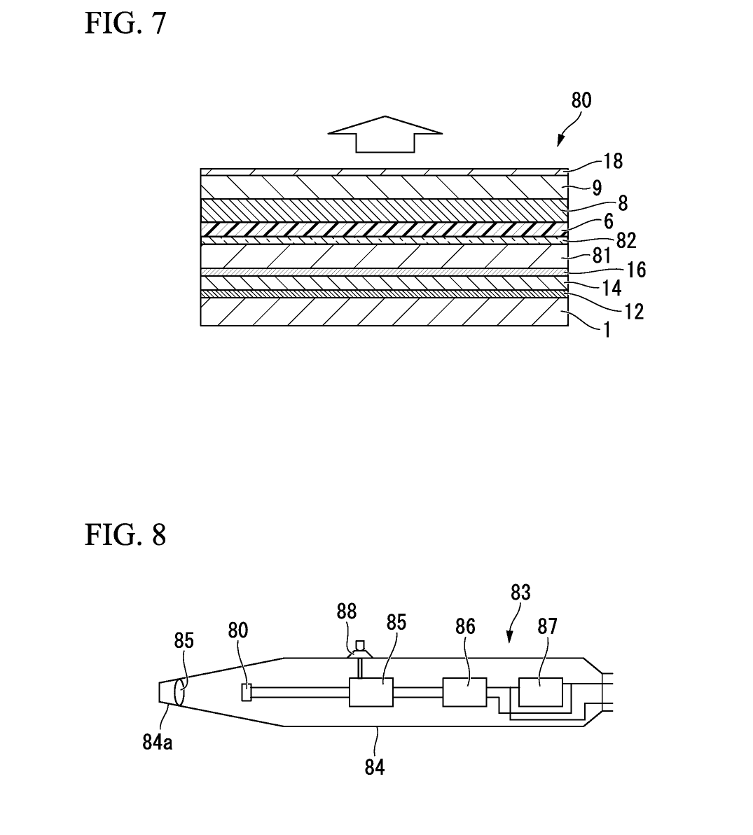

In a fluorescent display device 70 as an example of the organic light emitting device illustrated in FIG. 6, the same components as the fluorescent display device 20 of the first embodiment described above are denoted by the same reference numerals, and a description thereof will be omitted. Each component illustrated in FIG. 7 will be briefly described.

The fluorescent display device 70 of the present embodiment has a configuration in which the conductive layer 18 provided on the outer surface of the sealing substrate 9 in the configuration of the fluorescent display device 20 of the first embodiment is omitted, and instead, a conductive layer (a conductor) 8f formed as a thin metal film is provided along a wall portion of an inner surface of a black matrix 7 surrounding the periphery of the fluorescent layers 8R, 8G and 8B.

The conductive layer 8f is formed as, for example, a thin film of an excellent conductivity metal such as Ag, Au or Pt. The conductive layer 8f in this case may be a thin metal film or may have a structure in which particles are densely arranged. Further, metal particles constituting the thin metal film may not necessarily be in a spherical shape or may be in a spheroidal shape, a circular columnar shape, a polygonal columnar shape or an asymmetric shape.

The fluorescent display device 70 having the configuration illustrated in FIG. 6 is capable of the same display as the fluorescent display device 20 of the first embodiment described previously and obtaining the same operation and effects as the antistatic function. Further, if the structure illustrated in FIG. 6 and the structure illustrated in FIG. 1 are compared in terms of charging, the structure illustrated in FIG. 6 has a high shielding function against external static electricity or the like and achieves an effect such that display abnormality can be effectively suppressed. Further, if the conductive layer 8f is formed to surround each of the fluorescent layers 8R, 8G and 8B, coupling with the fluorescent light emission occurs due to an action of surface plasmons excited on the surface of the conductive layer 8f of a metal, and thus there is an effect such that light intensity can be improved.

Further, in the structure of the present embodiment, the black matrix 7 itself may be formed as a light-shielding conductive film.

In the structure of FIG. 6, it is possible to reflect and reuse scattered light using the conductive layer 8f, in addition to the antistatic purpose, thereby providing a brighter fluorescent display device 70.

Further, the embodiments listed in FIGS. 3 to 6 are not limited to a single embodiment and may be an embodiment obtained by combining some of the embodiments at the same time. When the conductive film is formed on the back surface of the sealing substrate 9, the surface of the fluorescent layer, or the interface between the fluorescent layer and the substrate, giving a periodic multilayer structure may cause a diffraction effect, thereby improving light extraction efficiency while light is passing through the periodic multilayer structure.

### Seventh Embodiment

FIG. 7 is a schematic cross-sectional view illustrating an example of an organic laser element as an example of an organic light emitting device according to a seventh embodiment of the present invention.

In an organic laser element 80 as an example of the organic light emitting device illustrated in FIG. 7, the same components as the fluorescent display device 20 of the first embodiment described above are denoted by the same reference numerals, and a description thereof will be omitted. Each component illustrated in FIG. 7 will be briefly described.

The organic laser element 80 of the present embodiment includes a wavelength conversion layer 81 and a semi-transparent mirror 82 on a second electrode 16, in addition to the light emitting layer 14 constituting the organic EL element 10 and the first electrode 12 and the second semi-transparent electrode 16 on both sides of the light emitting layer 14 in the configuration of the fluorescent display device 20 of the first embodiment. A sealing material 6 is formed on the semi-transparent mirror 82, a fluorescent layer 8 and a sealing substrate 9 are provided on the sealing material 6, and a conductive layer 18 that is the same as that of the first embodiment described above is formed on an outer surface of the sealing substrate 9.

The fluorescent layer 8 may be any of the fluorescent layers 8R, 8G and 8B described in the previous embodiment. Since the organic laser element 80 of the present embodiment has no particular need to constitute a pixel and need only emit at least one color of light, i.e., a laser light having a desired color, a structure in which one fluorescent layer 8 is provided is illustrated in the example of FIG. 7. It is to be understood that when light is emitted for each color in a multicolor light emitting laser, any of necessary fluorescent layers 8R, 8G and 8B may be arranged in parallel and the driving unit described in the above embodiment may be provided to switch and use the emitted light.

The organic laser element 80 having the configuration illustrated in FIG. 7 emits the light from the light emitting layer 14, similar to the fluorescent display device 20 of the first embodiment described previously. Since the organic laser element 80 includes the wavelength conversion layer 81 and the semi-transparent mirror 82 above the light emitting layer 14, the organic laser element 80 has a laser emitting function. Accordingly, a high-directivity laser beam having a full width at half maximum of several nm can be obtained by setting transmittance of the semi-transparent mirror 82 on the light emitting side of a microcavity to 1%. Further, a second harmonic can be generated to obtain a short wavelength by providing the wavelength conversion layer 81.

Even in the organic laser element 80 of the present embodiment, it is possible to obtain the same operation and effects as the structure of the first embodiment described above as the antistatic function by providing the conductive layer 18.

The organic laser element 80 illustrated in FIG. 7 may be applied, for example, to a laser pointer device 83 having a configuration illustrated in FIG. 8.

In the laser pointer device 83 of this embodiment, a pencil type housing 84, a condenser lens 85, the organic laser element 80 having the structure illustrated in FIG. 7, a light emitting circuit 85, a boosting circuit 86, and a battery 87 are incorporated. The condenser lens 85 is built in a front end portion 84a of the housing 84. The organic laser element 80 is built on the inner side from a mounting position of the condenser lens 85 in the housing 84. The light emitting circuit 85 is provided in a central portion in a longitudinal portion of the housing 84. The boosting circuit 86 and the battery 87 are incorporated on the side of a rear end portion of the housing 84. The organic laser element 80, the light emitting circuit 85, the boosting circuit 86, and the battery 87 are connected by wirings. The laser pointer device 83 is configured so that a voltage boosted by the boosting circuit 86 from the battery 87 can be applied to the first electrode 12 and the second electrode 16 of the organic laser element 80 from the light emitting circuit 85. Further, a lighting switch 88 that turns on and off power to be supplied to the organic laser element 80 via the light emitting circuit 85 is provided outside a center in the length direction of the housing 84.

The laser pointer device 83 illustrated in FIG. 8 may be used as a laser pointer device by switching emission and non-emission of a laser light from the organic laser element 80 by an on and off manipulation of the lighting switch 88. In this case, since the conductive layer 18 is provided in the organic laser element 80, it is possible to suppress an abnormal operation caused by external static electricity and to use the laser pointer device by switching reliable emission and non-emission of the laser light.

Further, the structure of each embodiment described in the previous embodiments is the structure of the organic light emitting device, but the structure may be applied to the organic light emitting device as well as an organic laser device having the structure as in the present embodiment. Or, the structure of each embodiment may be applied to a display device that performs display through light-light conversion of a fluorescent material using liquid crystal as an optical shutter for LED light. Further, the structure of each embodiment may be applied to an organic light emitting device that performs display through light-light conversion of a fluorescent material with laser light using quantum dots.

### Eighth Embodiment

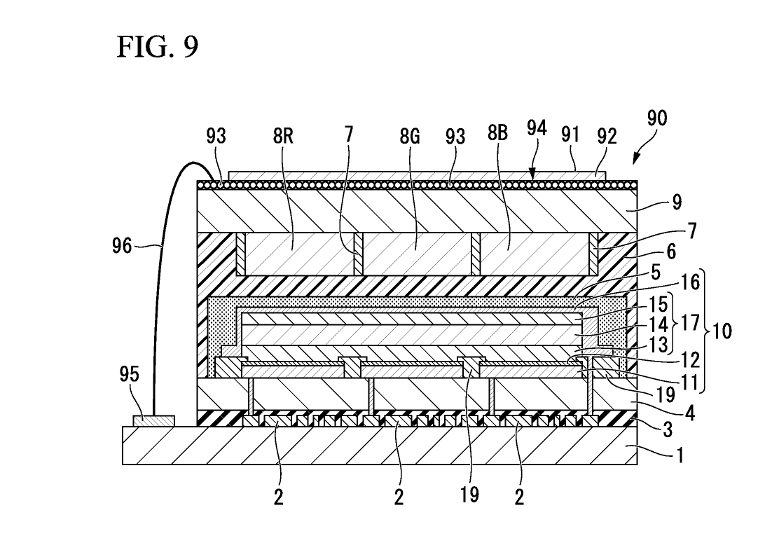

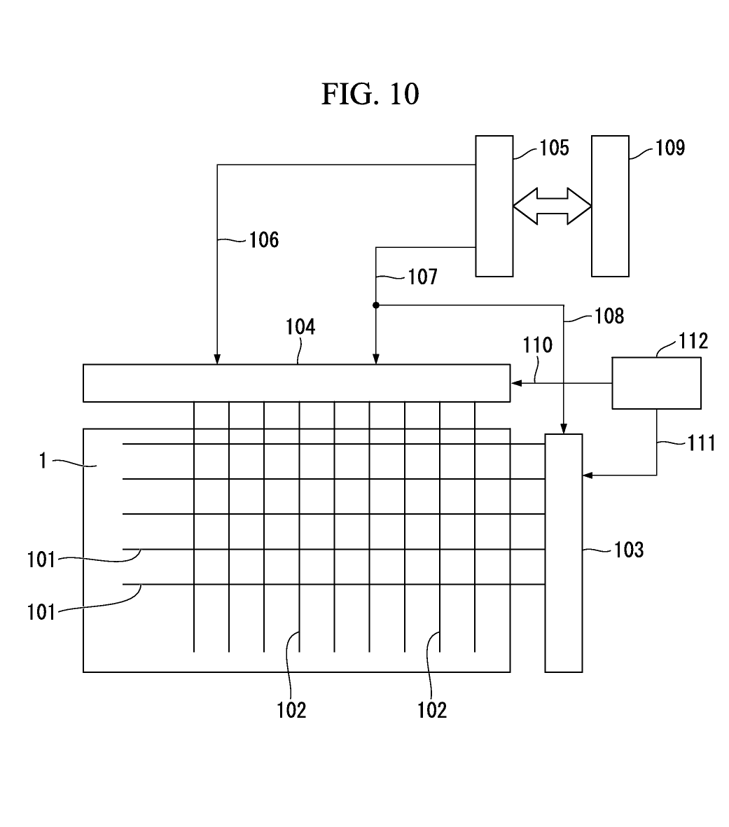

FIG. 9 is a schematic cross-sectional view illustrating an organic light emitting device according to an eighth embodiment of the present invention.

In a fluorescent display device 90 as an example of the organic light emitting device illustrated in FIG. 9, the same components as the fluorescent display device 20 of the first embodiment described above are denoted by the same reference numerals, and a description thereof will be omitted.

The fluorescent display device 90 of the present embodiment has a configuration in which the conductive layer 18 provided on the outer surface of the sealing substrate 9 in the configuration of the fluorescent display device 20 of the first embodiment is omitted, and instead, a conductive layer 94 formed by dispersing conductive particles (conductor) 93 in a sealing material 92 of a circularly polarizing plate 91 provided on an outer surface of a sealing substrate 9 is provided. Further, in the structure of the eighth embodiment, a ground terminal 95 for a TFT circuit is provided in an edge portion of a surface of the substrate 1. The fluorescent display device 90 has a structure in which the conductive layer 94 is electrically connected to the ground terminal 95 via a conductor 96 such as a bonding wire.

The conductive particles 93 constituting the conductive layer 94 may have the same configuration as that of the conductive particles applied to the conductive layer 18 of the first embodiment described above.

The fluorescent display device 90 having the configuration illustrated in FIG. 9 is capable of the same display as the fluorescent display device 20 of the first embodiment described previously and obtaining the same operation and effects as the antistatic function.

In the fluorescent display device 90 configured in this manner, it is possible to more reliably prevent charges from being accumulated in the conductive layer 94 by connecting the conductive layer 94 to the ground terminal 95 via the conductor 96. Accordingly, a charge shielding function is improved and there is an effect such that the display abnormality against external static electricity can be further suppressed.

In the present embodiment, transparency of the sealing material 92 is not limited and a sealing material having any transparency may be applied. In other words, the sealing material 92 is limited to a transparent one on the surface of the sealing substrate 9 of glass, but this limitation is relaxed in a case in which the conductive particles 93 are used in the sealing material 92. An amount of dispersion is not particularly limited, and it is apparent that an excellent antistatic capability is obtained as the amount of dispersion is greater.

FIG. 10 illustrates an example of a wiring structure of an organic EL panel and a connection structure of a driving circuit applied when a ground terminal 95 is provided in the fluorescent display device 90 illustrated in FIG. 9. Scanning lines 10 and signal lines 102 are wired in a matrix in a plan view with respect to the substrate 1. Each scanning line 101 is connected to a scanning circuit 103 provided in one side edge portion of the substrate 1. Each signal line 102 is connected to a video signal driving circuit 104 provided in the other side edge portion of the substrate 1. More specifically, a driving element (a driving unit) such as a thin film transistor is incorporated in each intersection between the scanning line 101 and the signal line 102. A pixel electrode is connected to each driving element. This pixel electrode corresponds to the reflecting electrode 11 of the structure illustrated in FIG. 9. The reflecting electrode 11 corresponds to the first electrode 12 that is a transparent electrode.

The scanning circuit 103 and the video signal driving circuit 104 are electrically connected to a controller 105 via control lines 106, 107 and 108. The controller 105 is operatively controlled by a central processing unit 109. Further, a power supply circuit 112 is connected to the scanning circuit 103 and the video signal driving circuit 104 via separate power lines 110 and 111.

Further, it is preferable to provide ground, but the ground is not essential. In each embodiment described above, a sufficient antistatic effect is achieved even without the ground. Further, a ground position is not particularly limited, but the ground position may be any position in the vicinity.

In one aspect of the present invention, it is possible to provide an antistatic method for an organic light emitting device by adopting the structure of each embodiment described above.

For example, the antistatic method for the organic light emitting device 20 adopting the structure of the first embodiment will be described. The organic light emitting device 20 includes the organic light emitting element 10, the paired substrates 1 and 9, and the fluorescent layers 8R, 8G and 8B. The organic light emitting element 10 includes the light emitting layer 14, and the pair of electrodes 12 and 16 having the light emitting layer 14 interposed therebetween. The organic light emitting element 10 is provided between the paired substrates 1 and 9. The fluorescent layers 8R, 8G and 8B, which perform fluorescence conversion, are provided outside the electrode 16 on the side from which the light emitted from the light emitting layer 14 is extracted. In other words, the fluorescent layers 8R, 8G and 8B, which perform fluorescence conversion, are provided above the electrode 16 on the side from which the light emitted from the light emitting layer 14 is extracted. The fluorescent layers 8R, 8G and 8B, which perform fluorescence conversion, perform the fluorescence conversion on the color of the light. The fluorescent layers 8R, 8G and 8B are layers that absorb light having a specific wavelength. With the antistatic method for the organic light emitting device 20 having such a configuration, it is possible to realize antistatic electricity of the organic light emitting device 20 by arranging the conductive layers 18 and 31 as conductors on the substrate 9 on the side from which the light is extracted.

Further, for example, the antistatic method for the organic light emitting device 40, 50, 60 or 70 will be described. The organic light emitting device 40, 50, 60 or 70 includes the organic light emitting element 10, the paired substrates 1 and 9, and the fluorescent layers 8R, 8G and 8B. The organic light emitting element 10 includes the light emitting layer 14, and the pair of electrodes 12 and 16 having the light emitting layer 14 interposed therebetween. The organic light emitting element 10 is provided between the paired substrates 1 and 9. The fluorescent layers 8R, 8G and 8B are provided outside the electrode 16 on the side from which the light emitted from the light emitting layer 14 is extracted. In other words, the fluorescent layers 8R, 8G and 8B, which perform fluorescence conversion, are provided above the electrode 16 on the side from which the light emitted from the light emitting layer 14 is extracted. The fluorescent layers 8R, 8G and 8B, which perform fluorescence conversion, perform fluorescence conversion on the color of the above light. The fluorescent layers 8R, 8G and 8B are layers that absorb light having a specific wavelength. In the antistatic method for the organic light emitting device 40, 50, 60 or 70 having such a configuration, it is possible to realize antistatic electricity for the organic light emitting device 40, 50, 60 or 70 by arranging the conductor inside or around the fluorescent layers 8R, 8G and 8B.

It is possible to realize antistatic electricity for the organic light emitting device by grounding the conductive layer 18 or 31 provided on the substrate 9 or the conductors 8a, 8b, 8c, 8d, 8e, or 8f provided inside or around the fluorescent layers 8R, 8G and 8B through connection to the power supply 112 for the electrodes having the light emitting layer 14 interposed therebetween.

### EXAMPLES

Hereinafter, the present invention will be further described in detail based on examples, but the present invention is not limited to structures of the following examples.

### Example 1

In Example 1, the organic EL element having the structure illustrated in FIG. 2 was prepared. A fluorescent substrate was prepared as follows.

Indium-tin oxide (ITO) was formed to have a film thickness of 10 nm on one surface of a glass substrate of 0.7 mm to be coated with a fluorescent material by a sputtering method. In the present example, the ITO was formed, but the ITO is not essential. An SnO₂ or In₂O₃ film may be formed. A circularly polarizing plate or the like may be adhered to the substrate for external light reflection. In this case, conductive particles including carbon may be scattered to and mixed with an adhered layer. In this case, it is to be understood that the conductive particles may be metallic fine particles. A case in which an ultra-thin metal film with a thickness of several nm is formed is also included in one aspect of the present invention.

A red fluorescent layer, a green fluorescent layer, and a light distribution film adjustment layer for blue light emission having a width of 3 mm were formed on a back surface of the substrate on which the conductive film was formed.

First, for formation of the red fluorescent layer, 15 g of ethanol and 0.22 g of γ-glycidoxypropyltriethoxysilane were added to 0.16 g of colloidal silicon dioxide having an average particle diameter of 5 nm and stirred for 1 hour at room temperature in an open system. This mixture and 20 g of a red fluorescent material K₅Eu_{2.5}(WO₄)_{6.25} were transferred to a mortar, triturated well, and heated for 2 hours in an oven of 70° C. and for 2 hours in an oven of 120° C. to obtain surface-modified K₅Eu_{2.5}(WO₄)_{6.25}. Next, 30 g of polyvinyl alcohol dissolved in a mixed solution (300 g) of water/dimethyl sulfoxide=1/1 was added to 10 g of the surface-modified K₅Eu_{2.5}(WO₄)_{6.25} and stirred by a dispersing machine to prepare a coating liquid for forming a red fluorescent material. The coating liquid for forming the red fluorescent material prepared in this manner was coated in a desired position to a width of 3 mm on the glass using a screen printing method. Subsequently, it was heated and dried for 4 hours in a vacuum oven (conditions: 200° C. and 10 mmHg) to form the red fluorescent layer.

Next, for formation of the green fluorescent layer, 15 g of ethanol and 0.22 g of γ-glycidoxypropyltriethoxysilane were added to 0.16 g of an aerosil having an average particle diameter of 5 nm and stirred for 1 hour at room temperature in an open system. This mixture and 20 g of a green fluorescent material Ba₂SiO₄:Eu²⁺ were transferred to a mortar, triturated well, and heated for 2 hours in an oven of 70° C. and for 2 hours in an oven of 120° C. to obtain surface-modified Ba₂SiO₄:Eu²⁺. Next, 30 g of polyvinyl alcohol dissolved in a mixed solution (300 g) of water/dimethyl sulfoxide=1/1 was added to 10 g of the surface-modified Ba₂SiO₄:Eu²⁺ and stirred by a dispersing machine to prepare a coating liquid for forming a green fluorescent material. The coating liquid for forming the green fluorescent material prepared in this manner was coated in a desired position to a width of 3 mm on the glass using the screen printing method. Subsequently, it was heated and dried for 4 hours in a vacuum oven (conditions: 200° C. and 10 mmHg) to form the green fluorescent layer.

Next, in a portion in which the blue fluorescent layer was originally to be arranged, 30 g of polyvinyl alcohol dissolved in a mixed solution (300 g) of water/dimethyl sulfoxide=1/1 was added and stirred by a dispersing machine to prepare a coating liquid for forming a layer. The coating liquid for forming a layer prepared in this manner was coated to have a width of 3 mm in a desired position on the glass using a screen printing method. Subsequently, it was heated and dried for 4 hours in a vacuum oven (conditions: 200° C. and 10 mmHg) to form a transparent layer of a resin containing no fluorescent material in a portion in which the blue fluorescent layer was originally to be arranged.

Meanwhile, paired organic EL element substrates were prepared as follows.

A reflecting electrode was formed of silver to have a film thickness of 100 nm on a glass substrate with a thickness of 0.7 mm by a sputtering method, and indium-tin oxide (ITO) was formed on the reflecting electrode to have a film thickness of 20 nm by the sputtering method to form a reflecting electrode (the anode) as the first electrode. The first electrode width was patterned into 90 stripes having a width of 2 mm by a general photolithography method.

Next, SiO₂ of the first electrode was stacked to 200 nm by the sputtering method and patterned to cover an edge portion of the first electrode by a conventional photolithography method. Here, a short side was covered with a SiO₂ by 10 μm from an edge of the first electrode. The resultant substrate was washed with water, subjected to pure water ultrasonic washing for 10 minutes, subjected to acetone ultrasonic washing for minutes, subjected to vapor washing with isopropyl alcohol for 5 minutes, and then dried for 1 hour at 100° C.

Next, this substrate was fixed to a substrate holder in an in-line type resistance heating deposition apparatus and evacuation was performed to vacuum of 1×10⁻⁴ Pa or less. Each organic layer was then formed. First, the hole injection layer having a film thickness of 100 nm was formed using 1,1-bis-di-4-tolylamino-phenyl-cyclohexane (TAPC) as a hole injection material by a resistance heating deposition method.

Next, the hole transport layer with a thickness of 40 nm was formed using N,N′-di-1-naphthyl-N,N′-diphenyl-1,1′-biphenyl-1,1′-biphenyl-4,4′-diamine (NPD) as a hole transport material by the resistance heating deposition method.

Then, a blue organic light emitting layer (thickness: 30 nm) was formed on a desired blue light emitting pixel on the hole transport layer. This green organic light emitting layer was prepared by co-evaporating 1,4-bis-triphenylsilyl benzene (UGH-2) (a host material) and bis[(4,6-difluorophenyl)-pyridinato-N,C2′]picolinate iridium (III) (FIrpic) (a blue phosphorescent dopant) at respective deposition rates of 1.5 Å/sec and 0.2 Å/sec.

Then, the hole blocking layer (thickness: 10 nm) was formed on the light emitting layer using 2,9-diphenyl-4,7-dimethyl-1,10-phenanthroline (BCP).

Then, the electron transport layer (thickness: 30 nm) was formed on the hole blocking layer using tris-(8-hydroxyquinoline) aluminum (Alq3).

Then, the electron injection layer (thickness: 0.5 nm) was formed on the electron transport layer using lithium fluoride (LiF).

Then, a semi-transparent electrode was formed as the second electrode. First, the above substrate was fixed to a chamber for metal deposition. Next, a shadow mask for forming the second electrode (a mask having an opening to form a second electrode having a width of 2 mm in a stripe shape in a direction against the stripe of the first electrode) and the substrate were aligned, and magnesium and silver were co-evaporated on a surface of the electron injection layer at a deposition rate of 0.1 Å/sec and 0.9 Å/sec using a vacuum deposition method to form magnesium silver (thickness: 1 nm) in a desired pattern. Moreover, silver (thickness: 19 nm) was formed in a desired pattern at a deposition rate of 1 Å/sec for the purpose of emphasizing the interference effect and preventing a voltage drop due to wiring resistance in the second electrode. Thus, the second electrode was formed.

Here, in the organic EL element, a microcavity effect (an interference effect) appears between the reflecting electrode (the first electrode) and the semi-transparent electrode (the second electrode), thereby increasing front luminance and more efficiently propagating emission energy from the organic EL element to the fluorescent layer and the alignment improvement layer. Further, similarly, an emission peak and a full width at half maximum were adjusted to be 460 nm and 50 nm by the microcavity effect, respectively. Next, using a plasma CVD method, an inorganic protection layer of SiO₂ with a thickness of 3 μm was patterned from an edge of the display unit to a sealing area of 2 mm up, down, left and right using a shadow mask.

The organic EL element substrate and the fluorescent substrate prepared as described above were positioned by a positioning marker formed outside the display unit. Further, the fluorescent substrate was coated with a thermosetting resin in advance, and both of the substrates were brought in close contact with each other via the thermosetting resin, heated for 2 hours at 90° C., cured, and bonded. Further, this bonding process was performed under a dry air environment (moisture amount: −80° C.) for the purpose of preventing organic EL from being deteriorated due to moisture.

Finally, the organic EL display device was completed by connecting terminals formed around the substrate to an external power supply. In the organic light emitting layer interposed between the fluorescent substrate and the organic EL substrate, an electronic circuit formed on the light emitting layer side of each substrate, and a plurality of pixels arranged in a matrix in a spreading direction of the layer are formed. A collection of respective pixels arranged in the matrix is adapted to form a display area when viewed from the fluorescent substrate side.

In each pixel constituting the display area, current injection to the light emitting layer is independently performed by supply of a signal via the electronic circuit. In each pixel, intensity of the excitation light for the fluorescent material generated by a magnitude of the injected current is changed and light transmission is controlled. Accordingly, any image can be displayed in the display area.

As a result, it was possible to obtain a desired excellent image by applying desired current to a desired stripe-shaped electrode using the external power supply.

### Example 2

In Example 1 above, the structure in which the conductive layer or the conductive particles are formed on the light emitting side of the fluorescent substrate was adopted. However, the present example is not limited thereto and a structure in which a conductive layer with a thickness of 10 nm is formed on the substrate surface coated with a fluorescent material, as in the structure illustrated in FIG. 2, was prepared.

In this case, the conductive layer is not limited to the ITO at all as in Example 1, and any conductive layer with a thickness of about 10 nm through which light is transmitted even when a metal is used may be applied. The conductive layer need not be formed on the entire surface, and a structure in which a thin metal film is formed in a portion of the pixel may be used.

If the conductive layer is formed on the substrate surface coated with the fluorescent material in this way, it is possible to further improve electrical conductivity as compared with the structure in which the conductive layer is formed on the outer surface of the substrate. Accordingly, it was possible to enhance the shielding function and obtain an effect such that display abnormality caused by external static electricity or the like can be further suppressed.

### Example 3

A structure in which the conductive particles are contained inside the fluorescent layer as illustrated in FIG. 3 was prepared.

Unlike Example 1, 1 mg of Au particles having a size of 50 nm was mainly added to a coating liquid for forming a red fluorescent material and dispersed uniformly. 1 mg of Ag particles 20 having a size of 20 nm was primarily added to a coating liquid for forming a green fluorescent material and dispersed uniformly. 1 mg of Al particles having a size of 20 nm was primarily added to a coating liquid for forming a blue fluorescent material and dispersed uniformly.

If the fluorescent layer is formed by applying such a coating material obtained by dispersing the metal particles, it is possible to further improve electrical conductivity. Accordingly, it is possible to enhance a shielding function and further suppress display abnormality caused by external static electricity or the like.

Further, surface plasmons excited on surfaces of the metal particles are coupled with fluorescent light emission, thereby enhancing light intensity and improving luminance by 5 to 10% as compared with a structure in which the metal particles are not dispersed in a fluorescent layer.

### Example 4

As illustrated in FIG. 4, a Ag thin film with a thickness of about nm was arranged in an inner bottom of the fluorescent layer disposed on the light emitting layer side. Since the film was a very thin metal film, a thickness may not have been uniform, the film may have been absent from some portions, and an unevenness may have been large.

With an organic EL element of the present example prepared in this manner, it is possible to further improve electrical conductivity. Accordingly, effects such that a shielding function can be enhanced and display abnormality caused by external static electricity or the like can be further suppressed are accomplished.

Further, surface plasmons excited on the surface of the Ag thin film are coupled with fluorescent light emission, thereby enhancing the light intensity and improving luminance by 5 to 10%.

### Example 5

The present example is the same as Example 1 except for the following. That is, the light emitting layer has a vertically two-layered structure. A Ag thin film with a thickness of about 10 nm was arranged at an interface of the layers to obtain the two-layered structure in which the fluorescent layer is vertically divided.

With an organic EL element of the present example prepared in this manner, it is possible to further improve the electrical conductivity. Accordingly, effects such that the shielding function is enhanced and display abnormality caused by external static electricity or the like can be further suppressed are achieved. Further, surface plasmons excited on the surface of the Ag thin film were coupled with fluorescent light emission, thereby enhancing light intensity and improving luminance by 5 to 10%.

### Example 6

The structure illustrated in FIG. 6 was prepared. That is, in this structure, the respective fluorescent layers for performing RGB color display were surrounded by partition walls in a black matrix. In the present example, at least a surface in contact with the fluorescent material in the partition wall surrounding each fluorescent pixel was formed as a Ag thin film with a thickness of about 10 nm.

With the organic EL element of the present example prepared in this manner, it is possible to further improve the electrical conductivity. Accordingly, effects such that the shielding function can be enhanced and display abnormality caused by external static electricity or the like can be further suppressed are achieved.

Further, surface plasmons excited on the surface of the metal layer provided on the inner surface of the partition wall of the black matrix were coupled with fluorescent light emission, thereby enhancing light intensity. Luminance was improved by 5 to 10% as compared with a sample having a structure in which the metal layer is not provided.

### INDUSTRIAL APPLICABILITY

In the organic light emitting device according to an aspect of the present invention, the present invention may be applied to a device having any structure as long as the device is one in which an organic layer emits light. In particular, the present invention may be applied to an organic electroluminescent element, and more specifically, to an organic EL element or an organic laser capable of realizing a multicolor light emitting element with a wide viewing angle, high color purity, and high efficiency since the organic EL element or the organic laser has the specific configuration.

### REFERENCE SIGNS LIST

1 . . . substrate, 2 . . . TFT circuit (driving unit), 7 . . . black matrix, 8 . . . fluorescent layer, 8R . . . red fluorescent layer, 8G . . . green fluorescent layer, 8B . . . blue fluorescent layer, 8a, 8b, 8c . . . metal particles (conductive particles: conductor), 8d . . . conductive layer (conductor), 8e . . . conductive layer (conductor), 8f . . . conductive layer (conductor), 9 . . . sealing substrate, 10 . . . organic EL element, 12 . . . first electrode, 16 . . . second electrode, 17 . . . organic EL layer (organic light emitting element), 18 . . . conductive layer, 20, 30, 40, 50, 60, 70, 80, 90 . . . fluorescent display device (organic light emitting device), 31 . . . conductive layer, 80 . . . organic laser element (organic light emitting device), 81 . . . wavelength conversion layer, 82 . . . semi-transparent mirror, 83 . . . laser pointer device, 91 . . . polarizing plate, 92 . . . sealing material, 93 . . . conductive particles (conductor), 95 . . . terminal grounded, 96 . . . conductor, 101 . . . scanning line, 102 . . . signal line, 103 . . . scanning circuit, 104 . . . driving circuit, 105 . . . controller, 112 . . . power supply circuit.

1. An organic light emitting device comprising:
first and second substrates;
an organic light emitting element between the first and second substrates;
a driving unit located between the first and second substrates to drive the organic light emitting element;
a fluorescent layer provided on a first surface of the first substrate; and
a conductive layer with optical transparency provided on a second surface of the first substrate,
wherein the organic light emitting element includes a light emitting layer, and a pair of electrodes having the light emitting layer interposed therebetween,
the fluorescent layer is provided above the electrode on the side from which light emitted from the light emitting layer is extracted among the pair of electrodes,
the fluorescent layer performs fluorescence-conversion on a color of the light emitted from the light emitting layer,
the fluorescent layer includes a layer that absorbs light having a specific wavelength,
the first substrate has optical transparency,
light is emitted from the fluorescence conversion layer to the outside through the first substrate,
the fluorescent layer is arranged in a surface direction of the first substrate to form a pixel, and
the conductive layer overlaps at least an area in which the pixel is formed.

2. An organic light emitting device comprising:
first and second substrates;
an organic light emitting element between the first and second substrates;
a fluorescent layer between the first substrate and the organic light emitting element; and
a conductive layer with optical transparency between the first substrate and the fluorescent layer,
wherein the organic light emitting element includes a light emitting layer, and a pair of electrodes having the light emitting layer interposed therebetween,
the fluorescent layer is provided above the electrode on the side from which light emitted from the light emitting layer is extracted among the pair of electrodes,
the fluorescent layer performs fluorescence-conversion on a color of the light emitted from the light emitting layer, and
the fluorescent layer includes a layer that absorbs light having a specific wavelength.

3. An organic light emitting device comprising:
an organic light emitting element;
a driving unit that drives the organic light emitting element; and
a fluorescent layer on the organic light emitting element,
wherein the organic light emitting element includes a light emitting layer, and a pair of electrodes having the light emitting layer interposed therebetween,
the fluorescent layer is provided above the electrode on the side from which light emitted from the light emitting layer is extracted among the pair of electrodes,
the fluorescent layer performs fluorescence-conversion on a color of the light emitted from the light emitting layer,
the fluorescent layer includes a layer that absorbs light having a specific wavelength, and
conductive particles are mixed within the fluorescent layer.

4. An organic light emitting device comprising:
an organic light emitting element;
a fluorescent layer on the organic light emitting element; and
a conductive layer arranged within the fluorescent layer or in contact with the fluorescent layer,
wherein the organic light emitting element includes a light emitting layer, and a pair of electrodes having the light emitting layer interposed therebetween,
the fluorescent layer is provided above the electrode on the side from which light emitted from the light emitting layer is extracted,
the fluorescent layer performs fluorescence-conversion on a color of the light emitted from the light emitting layer, and
the fluorescent layer includes a layer that absorbs light having a specific wavelength

5. The organic light emitting device according to claim 1, wherein the conductive layer has unevenness.

6. The organic light emitting device according to claim 1, wherein the conductive layer has sheet resistance of 2×10³Ω·□ or less.

7. The organic light emitting device according to claim 1, further comprising:
a polarizing plate on the conductive film,
wherein the conductive layer is configured by scattering conductive particles in an adhesive material for adhering the polarizing plate to the first substrate.

8. The organic light emitting device according to claim 1, wherein the conductive layer has a periodic structure.

9. The organic light emitting device according to claim 1, wherein the conductive layer or the conductive particles are formed of a metal.

10. The organic light emitting device according to claim 1, wherein the conductive layer or the conductive particles are formed of particles containing one of ITO, SnO₂ and In₂O₃ or a mixture of the particles.

11. The organic light emitting device according to claim 1, wherein a ground terminal is included on the first substrate, and the conductive layer is electrically connected to the ground terminal.

12. The organic light emitting device according to claim 1, wherein the pair of electrodes are reflective electrodes, and an optical film thickness between reflective interfaces defined by the pair of reflective electrodes is set to enhance intensity of light having a specific wavelength among lights emitted from the light emitting layer.

13. An antistatic method for an organic light emitting device including first and second substrates, an organic light emitting element between the first and second substrates, and a fluorescent layer included on a first surface of the first substrate, the organic light emitting element including a light emitting layer and a pair of electrodes having the light emitting layer interposed therebetween, the fluorescent layer being provided above the electrode on the side from which light emitted from the light emitting layer is extracted among the pair of electrodes, the fluorescent layer performing fluorescence-conversion on a color of the light emitted from the light emitting layer, and the fluorescent layer including a layer that absorbs light having a specific wavelength,
wherein a conductor is arranged in the first substrate to prevent charging of the organic light emitting element.

14. An antistatic method for an organic light emitting device including first and second substrates, an organic light emitting element between the first and second substrates, and a fluorescent layer included on a first surface of the first substrate, the organic light emitting element including a light emitting layer and a pair of electrodes having the light emitting layer interposed therebetween, the fluorescent layer being provided above the electrode on the side from which light emitted from the light emitting layer is extracted among the pair of electrodes, the fluorescent layer performing fluorescence-conversion on a color of the light emitted from the light emitting layer, and the fluorescent layer including a layer that absorbs light having a specific wavelength,
wherein a conductor is arranged inside the fluorescent layer or around the fluorescent layer to prevent charging of the organic light emitting element.

15. The antistatic method for an organic light emitting device according to claim 13, characterized in that the conductor is grounded through connection to a power supply for the pair of electrodes.

16. The organic light emitting device according to claim 2, wherein the conductive layer has unevenness.

17. The organic light emitting device according to claim 4, wherein the conductive layer has unevenness.

18. The organic light emitting device according to claim 2, wherein the conductive layer has sheet resistance of 2×10³Ω·□ or less.

19. The organic light emitting device according to claim 4, wherein the conductive layer has sheet resistance of 2×10³Ω·□ or less.

20. The organic light emitting device according to claim 2, wherein the conductive layer has a periodic structure.

21. The organic light emitting device according to claim 4, wherein the conductive layer has a periodic structure.

22. The organic light emitting device according to claim 2, wherein the conductive layer or the conductive particles are formed of a metal.

23. The organic light emitting device according to claim 4, wherein the conductive layer or the conductive particles are formed of a metal.

24. The organic light emitting device according to claim 2, wherein the conductive layer or the conductive particles are formed of particles containing one of ITO, SnO₂ and In₂O₃ or a mixture of the particles.

25. The organic light emitting device according to claim 3, wherein the conductive layer or the conductive particles are formed of particles containing one of ITO, SnO₂ and In₂O₃ or a mixture of the particles.

26. The organic light emitting device according to claim 4, wherein the conductive layer or the conductive particles are formed of particles containing one of ITO, SnO₂ and In₂O₃ or a mixture of the particles.

27. The organic light emitting device according to claim 2, wherein a ground terminal is included on the first substrate, and the conductive layer is electrically connected to the ground terminal.

28. The organic light emitting device according to claim 2, wherein the pair of electrodes are reflective electrodes, and an optical film thickness between reflective interfaces defined by the pair of reflective electrodes is set to enhance intensity of light having a specific wavelength among lights emitted from the light emitting layer.

29. The organic light emitting device according to claim 3, wherein the pair of electrodes are reflective electrodes, and an optical film thickness between reflective interfaces defined by the pair of reflective electrodes is set to enhance intensity of light having a specific wavelength among lights emitted from the light emitting layer.

30. The antistatic method for an organic light emitting device according to claim 14, characterized in that the conductor is grounded through connection to a power supply for the pair of electrodes.
